(19) United States
(12) Patent Application Publication
(10) Pub. No.: US 2012/0031147 A1
(43) Pub. Date: Feb. 9, 2012

(54) Method and Apparatus for Machining Thin-Film Layer of Workpiece

(75) Inventors: Kunio Arai, Ebina-shi (JP); Yasuhiko Kanaya, Ebina-shi (JP); Kazuhisa Ishii, Ebina-shi (JP); Hiroshi Honda, Ebina-shi (JP)

(73) Assignee: Hitachi Via Mechanics, Ltd., Ebina-shi (JP)

(21) Appl. No.: 13/254,155

(22) PCT Filed: Feb. 24, 2010
(86) PCT No.: PCT/JP2010/052898

§ 371 Date: Oct. 27, 2011

(30) Foreign Application Priority Data
Mar. 3, 2009 (JP) 2009-049961

(51) Int. Cl. C03B 35/24; C03B 23/02

(52) U.S. Cl. 65/182.2

(57) ABSTRACT

An apparatus for machining a thin-film layer of a workpiece, which is a transparent glass on which a thin-film layer is disposed on a top surface thereof, includes a workpiece-underside support mechanism for supporting the workpiece in a vertical direction by an air floatation mechanism and a suction mechanism, a clamp device for gripping the workpiece so as to follow the movement in the vertical direction of the workpiece, and a machining head for machining the thin-film layer with a laser beam. The machining head machines the thin-film layer on the top surface of the workpiece by irradiating the workpiece with a laser beam entering through the underside of the workpiece. Further including nozzles, the thin-film layer is machined while the cooling medium is delivered from the nozzles disposed by the thin-film layer side.

### TECHNICAL FIELD

The present invention relates to a method for machining a thin-film layer of a workpiece and a thin-film layer machining apparatus for machining a thin-film layer of a workpiece, which is a transparent glass on which a thin-film layer is disposed on the top surface.

### BACKGROUND ART

As a transparent glass on which a thin-film layer is disposed on the top surface, a solar battery, for example, is known. FIG. 29 is a plan view showing a process for manufacturing a solar battery. In FIG. 29, a solar battery, which is a workpiece 101, is a transparent glass 102 on which a plurality of thin-film layers are formed on the surface. The plurality of thin-film layers are formed across the entire surface of the glass 102. Subsequently, a portion of the thin-film layers on the periphery of the glass 102 is removed (Edge Deletion). This removed portion is referred to as a removed portion 107.

FIG. 30 is a cross-sectional view for explaining the process for manufacturing the solar battery. FIG. 30(a) shows a first step, FIG. 30(b) shows a second step, FIG. 30(c) shows a third step, and FIG. 30(d) shows a final step. In the process for manufacturing the solar battery, first, as shown in FIG. 30(a), a first thin-film layer (rear surface electrode layer) 104 is disposed on the transparent glass 102. Subsequently, a first line groove P1 for insulating between a thin-film layer 1041 and a thin-film layer 1042 is formed. Next, as shown in FIG. 30(b), a second thin-film layer (light absorbing layer) 105 is disposed on top of the thin-film layer 104. Subsequently, a second line groove P2 for insulating between a thin-film layer 1051 and a thin-film layer 1052 is formed. Next, as shown in FIG. 30(c), a third thin-film layer (top surface electrode layer) 106 is disposed on top of the thin-film layer 105. Subsequently, a third line groove P3 for insulating between a thin-film layer 1061 and a thin-film layer 1062 of the thin-film layer 106 is formed. The third line groove P3 has a depth reaching the top surface of the thin-film layer 104. Finally, as shown in FIG. 30(d), portions of the three layers (thin-film layers 104, 105, and 106) on the periphery of the transparent glass 102 are removed. Hereinafter, the periphery portion from which the thin-film layers 104 to 106 are removed will be referred to as the removed portion 107. The width of the removed portion 107 is 10 to 15 mm. Further, the line spacings between the adjacent first line grooves P1, between the adjacent second line grooves P2, and between the adjacent third line grooves P3 are each 10 to 15 mm. Further, the spacing between the adjacent first line groove P1 and second line groove P2 and the spacing between the second line groove P2 and third line groove P3 are each 100 to 200 μm. In other words, the first to third line grooves P1, P2, and P3, which are arranged at spacings of 100 to 200 μm, are formed at spacings of 10 to 15 mm.

FIG. 31 is a perspective view showing a main part of a configuration of an apparatus for machining a thin-film layer that has been conventionally used. In the conventional thin-film layer machining apparatus, the workpiece is placed with the thin-film layer facing upwards and the thin-film layer is machined from the top surface side so that the thin-film layer is not damaged during machining and transporting the workpiece. In FIG. 31, the thin-film layer machining apparatus includes a bed 114, an X movement mechanism 110, and a Y movement mechanism 117. The X movement mechanism 110 is disposed on the bed 114. The X movement mechanism 110 includes a guide roller mechanism 113 which supports the bottom surface of the workpiece and a guide mechanism 112. The guide mechanism 112 clamps the workpiece 101 being fit to the bottom surface of the workpiece 101. The guide mechanism 112 reciprocally moves in the X direction (one axial direction on an orthogonal X-Y plane parallel to the surface of the bed 114) by means of a drive device (not shown) with supporting the side surface of the workpiece 101.

The Y movement mechanism 117 is disposed on a column 115 fixed to the bed 114. The Y movement mechanism 117 reciprocally moves in the Y direction along the column 115 by means of a Y driving mechanism (not shown). The Y direction is the direction of the other axis on the XY plane that is orthogonal to the X axis. A machining head 118 and an optical delivery system (not shown) are disposed on the Y movement mechanism 117. The machining head 118 reciprocally moves in the Z direction (direction that is perpendicular to the XY plane) by means of a Z driving mechanism (not shown).

The steps for forming the first to third line grooves P1 to P3 are as follows:

(1) A position in the Y direction of the machining head 118 is determined by the Y movement mechanism 117.

(2) After determining the position in the Y direction, the position in the Z direction (height) of the machining head 118 is determined.

(3) While moving the workpiece 101 in the X direction by means of the X movement mechanism 110, a laser beam is emitted from the machining head 118 to form the first to third line grooves P1 to P3.

(3-1) The first thin-film layer 104 is machined with a laser beam having a wavelength of 1064 nm.

(3-2) The second and third thin-film layers 105 and 106 are machined with a laser beam having a wavelength of 532 nm.

(4) After forming the third line groove P3, the periphery portion of the workpiece 101 is machined with a laser beam having a wavelength of 1064 nm to form the removed portion 107.

The first to third line grooves P1 to P3 and the removed portion 107 are machined by dedicated machining devices. In order to increase the machining efficiency, the line groove machining devices are respectively dedicated, while being arranged in a line. In the formation of the first to third line grooves P1 to P3, a beam of a spot diameter D is shifted by a fixed pitch 1, and the depths of the line grooves are controlled by the overlap ratio [(D−1)/D] %. Therefore, the total energy introduced into the overlap portion on the bottom of the groove is (the number of overlaps)×(the pulse energy). Thus, the injected energy discretely changes depending on the location within a range of from the beam energy itself to the beam energy multiplied by the number of overlaps.

The invention disclosed in Patent Document 1 is publicly known as this type of technology. An object of this invention is to machine with accuracy by maintaining the focal point of a laser beam at a fixed position when scribing an integrated solar battery by a laser beam. In the method for manufacturing a solar battery of this invention, an electrode layer is formed on an insulating substrate, and irradiated with a laser beam. Thereby the electrode layer is divided and patterned. A photoelectric conversion layer is layered on the electrode layer, and then irradiated with a laser beam. Thereby, the photoelectric conversion layer is divided and patterned. A aspect of this invention is that, when patterning the photoelectric conversion layer, the divided line edge in the electrode layer on the insulating substrate is used as a reference for the focal point of the laser beam, and thereby, the divided line in the electrode layer and the dividing line of the photoelectric conversion layer are overlapped each other.

### Patent Document 1: JP-A-10-303444

### DISCLOSURE OF THE INVENTION

### Problems to be Solved by the Invention

The machining in the conventional thin-film layer machining apparatus has a problem in that it is difficult to maintain the irradiation position for the laser beam at a fixed position. In other words, the tolerance of the board thickness of the workpiece 101 is ±0.5 mm, and the tolerance of the warp or deformation is ±1 mm. As mentioned above, in a conventional apparatus, the bottom surface of the workpiece 101 is supported by the guide roller mechanism 113. Therefore, the position of the top surface of the workpiece may change by ±1.5 mm, which is the sum of the tolerance of the board thickness and the tolerance of the warp or deformation. If the focusing height of the laser beam deviates from the design position, the machining is carried out in a defocused condition. Thus, the spot diameter varies. In this case, the groove widths of the first to third line grooves P1 to P3 cannot satisfy the permissible variation (±10% or less), or the target layer is not removed and remains due to insufficient energy density.

Further, there is also a problem related to restrictions of the pulse period (1/pulse frequency) of the laser beam. Basically, if the pulse period is shortened, the temperature of the beam overlap portion increases due to thermal conduction of the thin-film layer or glass. Consequently, detachment at the groove side walls from the substrate easily occurs. Thus, it has been necessary to set the pulse period to 0.04 ms or greater (a pulse frequency of 25 kHz or less). The pulse frequency at which the maximum output of a laser oscillator can be achieved is 80 to 120 kHz. In spite of this, the pulse frequency had to be decreased to 25 kHz or less, and thus the output utilization efficiency of the laser beam could not be enhanced.

A method of machining with a laser entering from the underside has been attempted (Patent Document 1), but this method did not reach practical application. The reason this method could not be practically utilized is that debris produced by the machining could not be sufficiently removed, and thus the insulation resistance decreased to approximately 50 MΩ due to the debris in the grooves. Therefore, the ideal insulation resistance of 2000 MΩ could not be obtained.

Therefore, a first problem to be solved by the present invention is to enable the irradiation position for the laser beam to be held in place, and thereby allow machining to be carried out such that the groove width satisfies the permissible variation, leading to an improvement in the quality of the worked portion.

Further, a second problem to be solved is to enhance the output utilization efficiency of the laser beam.

### Solutions to the Problems

In order to overcome the above-described problems, a first means is a method of machining a thin-film layer of a workpiece, which is a transparent glass on which a thin-film layer is disposed on the top surface thereof, including machining the thin-film layer on the top surface side with a laser beam entering through the underside of the workpiece in a state in which the workpiece is supported in the vertical direction by a compressed air and held by a clamp device which is movable to follow the movement of the workpiece in the vertical direction.

A second means is a method of machining a thin-film layer of a workpiece, which is a transparent glass on which a thin-film layer is disposed on the top surface thereof, wherein machining is carried out while a cooling medium is blown onto a machining portion.

A third means is an apparatus for machining a thin-film layer of a workpiece, which is a transparent glass on which a thin-film layer is disposed on the top surface thereof, the apparatus including a support device which supports the workpiece in the vertical direction by a compressed air, a clamp device which holds the workpiece and is movable to follow the movement of the workpiece in the vertical direction, and a laser machining head which machines the thin-film layer by a laser beam, wherein the laser device machines the thin-film layer on the top surface side by irradiation with a laser beam entering through the underside of the workpiece.

A fourth means is an apparatus for machining a thin-film layer of a workpiece, which is a transparent glass on which a thin-film layer is disposed on the top surface thereof, the apparatus including a nozzle for delivering a cooling medium, and a laser machining head which machines the thin-film layer by a laser beam, wherein during machining, the cooling medium is blown by the nozzle disposed by the thin-film layer side to a position at which the laser emitted from the laser machining head is incident on the thin-film layer.

### EFFECTS OF THE INVENTION

According to the present invention, the irradiation position for the laser beam can be held in place. Therefore, the machining can be carried out such that the groove width satisfies the permissible variation. As a result, the quality of the machined portion can be enhanced.

In addition, the thin-film layer can be machined from the underside while a cooling medium is blown on the top surface side. Therefore, even if the pulse period is shortened, enough insulation resistance can be obtained, and thus the output utilization efficiency of the laser beam can be enhanced.

### BRIEF DESCRIPTION OF THE DRAWINGS

FIG. 1 is a functional block diagram showing a configuration of a thin-film layer machining apparatus according to an embodiment of the present invention.

FIG. 2 is a perspective view for explaining the configuration of the thin-film layer machining apparatus main body shown in FIG. 1.

FIG. 3 is a view showing the details of a workpiece-underside support mechanism shown in FIG. 2.

FIG. 4 is a view showing a modified embodiment 1 of the workpiece-underside support mechanism shown in FIG. 3.

FIG. 5 is a view showing a modified embodiment 2 of the workpiece-underside support mechanism shown in FIG. 3.

FIG. 6 is a view showing a modified embodiment 3 of the workpiece-underside support mechanism shown in FIG. 3.

FIG. 7 is a view showing a modified embodiment 4 of the workpiece-underside support mechanism shown in FIG. 3.

FIG. 8 is a view showing the details of a workpiece side clamp mechanism shown in FIG. 2.

FIG. 9 is a view showing a modified embodiment of the workpiece side clamp mechanism shown in FIG. 8.

FIG. 10 is a view showing the details of a workpiece front end surface clamp mechanism shown in FIG. 2.

FIG. 11 is a view showing the details of a workpiece rear end surface clamp mechanism shown in FIG. 2.

FIG. 12 is a plan view showing a first arrangement example of the clamp mechanisms in the embodiment of the present invention.

FIG. 13 is a plan view showing a second arrangement example which is a modified embodiment of the first arrangement example of the clamp mechanisms shown in FIG. 12.

FIG. 14 is a plan view showing a third arrangement example of the clamp mechanisms in the embodiment of the present invention.

FIG. 15 is a plan view showing a fourth arrangement example of the clamp mechanisms in the embodiment of the present invention.

FIG. 16 is a plan view showing a fifth arrangement example of the clamp mechanisms in the embodiment of the present invention.

FIG. 17 is a plan view showing a sixth arrangement example of the clamp mechanisms in the embodiment of the present invention.

FIG. 18 is a view for explaining a first dust collector for machining the line grooves according to the embodiment of the present invention.

FIG. 19 is a side view showing the main parts of a column equipped with the first dust collector shown in FIG. 18.

FIG. 20 is a view for explaining a second dust collector for machining the line grooves according to the embodiment of the present invention.

FIG. 21 is a side view showing the main part of a column equipped with the second dust collector shown in FIG. 20.

FIG. 22 is an explanatory view of a third dust collector used in the case of forming a removed portion around the periphery of the workpiece in the embodiment of the present invention.

FIG. 23 is a vertical cross-sectional view of guide roller units disposed on both side surfaces in the X direction of an upper dust collection chamber.

FIG. 24 is an explanatory view of a fourth dust collector used in machining of a center portion in the embodiment of the present invention.

FIG. 25 is a side view showing the main parts of a column equipped with the fourth dust collector shown in FIG. 24.

FIG. 26 is a schematic view showing a dust prevention mechanism of an optical system in the embodiment of the present invention.

FIG. 27 is a view showing a configuration of the main parts of the optical system in the embodiment of the present invention.

FIG. 28 is a view showing a configuration of the optical system in the embodiment of the present invention when carrying out machining to remove the periphery of the workpiece by a high output laser.

FIG. 29 is a plan view showing a process for manufacturing a solar battery carried out in a related art.

FIG. 30 is a cross-sectional view for explaining the process for manufacturing a solar battery carried out in the related art.

FIG. 31 is a main perspective view showing main part of a configuration of an apparatus for machining a thin-film layer that has been used in a related art.

### DESCRIPTION OF EMBODIMENTS

The present invention relates to a technology for machining a workpiece, which is a transparent glass on which a thin-film layer is disposed on the top surface thereof, in consideration of the machining accuracy and machining efficiency. Basically, in the present invention, the workpiece is supported in the vertical direction by a compressed air, and the workpiece is held by a clamping device which follows the movement of the workpiece in the vertical direction. In this state, the thin-film layer on the top surface side is machined by a laser light entering through the underside of the workpiece. Hereinafter, an embodiment of the present invention will be explained with reference to the drawings.

### 1. Overall Configuration

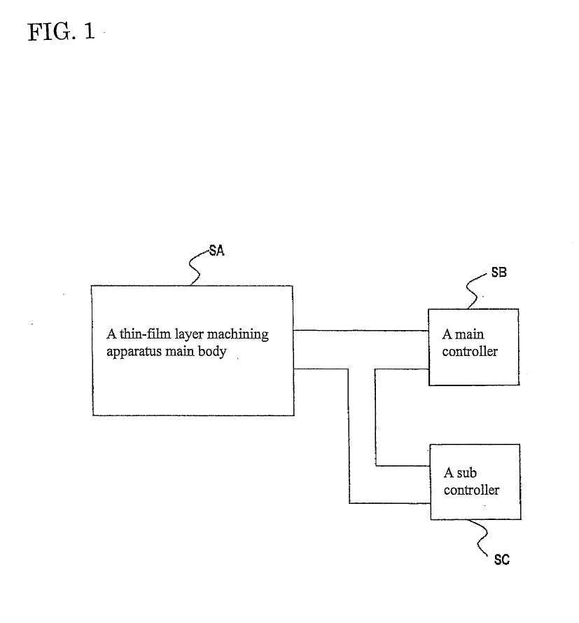

FIG. 1 is a functional block diagram showing the configuration of the thin-film layer machining apparatus according to an embodiment of the present invention. In

FIG. 1, the thin-film layer machining apparatus according to the present embodiment includes a thin-film layer machining apparatus main body SA, a main controller SB, and a sub controller SC. The thin-film layer machining apparatus main body SA is comprised of an XYZ positioning mechanism of a laser beam, a machining head, a laser oscillator, a vacuum device, a mist generating device, and the like. A laser controller, a motor driver, a pulse shaper driver, a galvanometer scanner driver, and the like are mounted in the sub controller SC. The main controller SB and the sub controller SC each include a CPU, ROM, and RAM. Each of the CPUs loads a program stored in their respective ROMs into their respective RAMs. Then each CPU executes a prescribed control defined by the program while using each RAM as a work area and data buffer.

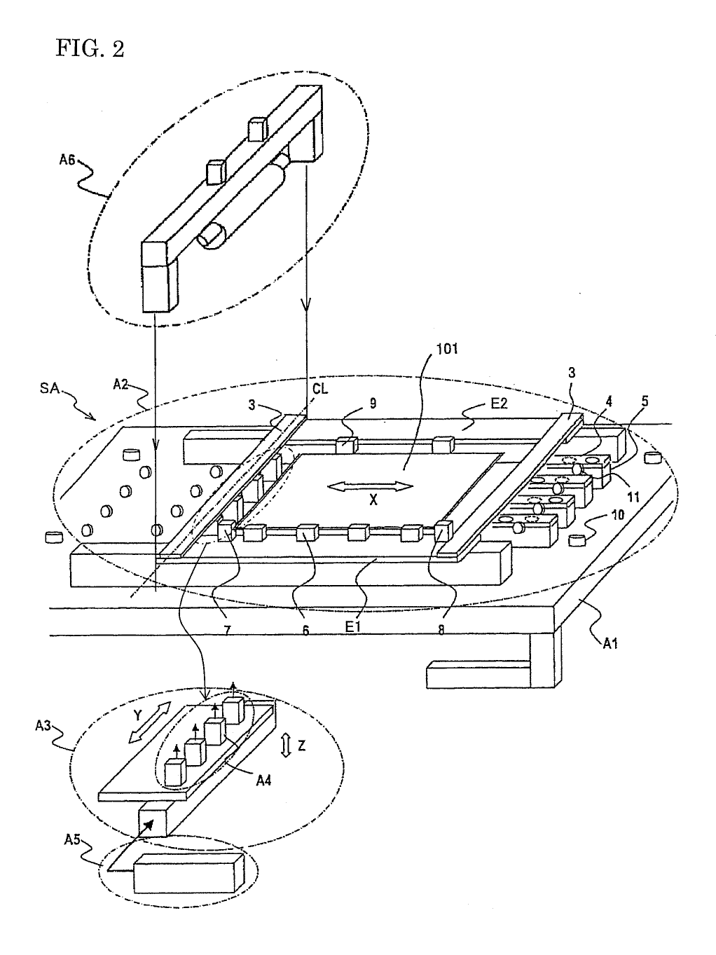

FIG. 2 is a perspective view for explaining the configuration of the thin-film layer machining apparatus main body. The left side of a center line CL is omitted from the drawing. In FIG. 2, the thin-film layer machining apparatus main body SA is comprised of a frame mechanism bed A1, an X movement mechanism A2, a Y movement mechanism A3, a machining head A4, a laser oscillator A5, and a column A6. The X movement mechanism A2 is disposed on the bed A1. The Y movement mechanism A3 is similarly disposed on the bed A1 in an orthogonal fashion relative to the X movement mechanism A2. The machining head A4 is united with a Z movement mechanism disposed on the Y movement mechanism A3. The column A6 is fixed on top of the bed A1. A dust collection mechanism disposed on the machining head, a position monitoring camera, and a height detection device for detecting the height are disposed on the column A6.

The X movement mechanism A2 is comprised of a first X driving mechanism (the details of this mechanism are omitted) E1, a second X driving mechanism (the details of this mechanism are omitted) E2, and a pair of connecting plates 3. The first X driving mechanism E1 is movable in the X direction by a motor (not shown). The second X driving mechanism E2 is movable parallel to the first X driving mechanism E1. One end of the connecting plate 3 is fixed to the first X driving mechanism E1. The other end of the connecting plate 3 is connected to the second X driving mechanism E2. With this configuration, the first and second X driving mechanisms E1 and E2 move simultaneously. The connecting part of the connecting plate 3 to the second X driving mechanism E2 are configured to slide in only the Y direction, in order not to load the second X driving mechanism E2 in the Y direction.

A workpiece side clamp mechanism 6 is provided to each of the first and second X driving mechanisms E1 and E2. As will be explained later, the workpiece side clamps 6 is movable (follower type) in the vertical direction even during the clamping operation of the workpiece 101. Further, a workpiece front end surface clamp mechanism 7 and a workpiece rear end surface clamp mechanism 8 are provided to the first X driving mechanism E1. The former determines the position of the front end surface of the workpiece 101, and the latter determines the position of the rear end surface of the workpiece 101, and both are retracted during unclamping. A workpiece side surface pressing mechanism 9 is provided to the second X driving mechanism E2.

A workpiece-underside support mechanism 4 is disposed on the bed A1 via a support frame 5. The workpiece-underside support mechanism 4 has a function to lift the workpiece and a function to suck the workpiece, in order to support the workpiece 101 without contact. The workpiece-underside support mechanism 4 is also disposed on the not-illustrated side of the center line CL in the drawing. A pair of guide rollers 10 is disposed on each end of the bed A1 in the X direction. The guide rollers 10 regulate any displacement in the Y direction when sending the workpiece 101 in the X direction up to an input standby position (clamp position). The guide rollers 10 rise to a position which is the same level as the end surface of the workpiece 101 only during loading of the workpiece 101. When the workpiece 101 reaches the clamp position, the guide rollers 10 drop down and enter standby. A support roller 11 is provided to the support frame 5. The support rollers 11 are disposed such that the peak height of their outer diameters is 0.1 mm higher than the top surface height of the supports 46. The support rollers 11 support the workpiece 101 when the workpiece-underside support mechanism 4 is inoperable, and enables the workpiece 101 to be moved manually.

### 2. Workpiece-Underside Support Mechanism

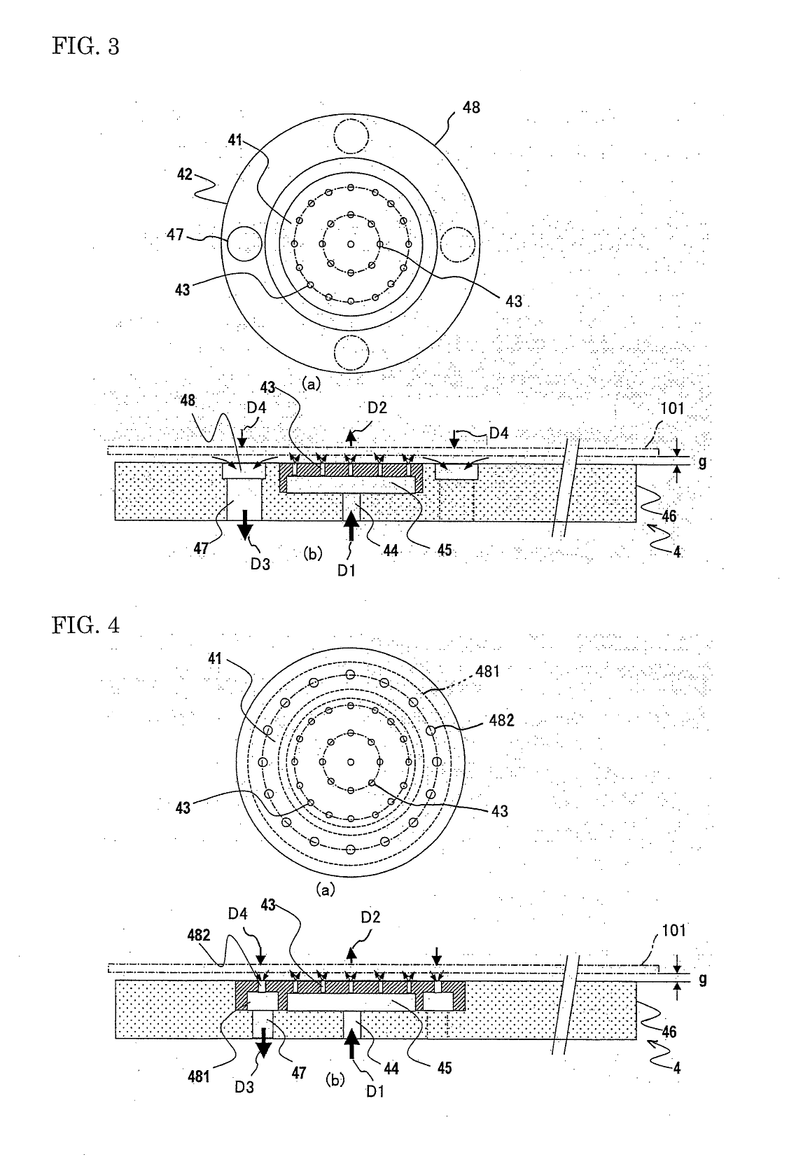

2.1 Basic Configuration The workpiece 101 is supported in a floating state on an air cushion from the bottom surface side. The mechanism for this support is the workpiece-underside support mechanism 4. FIG. 3 is a view showing the details of the workpiece-underside support mechanism 4. FIG. 3(a) is a plan view of the main parts, and FIG. 3(b) is a cross-sectional view.

As shown in FIG. 3, the workpiece-underside support mechanism 4 has a floatation mechanism 41 and a suction mechanism 42. The mechanisms 41 and 42 are disposed on a planar support 46. The floatation mechanism 41 is a flat air bearing having an orifice array which is disposed in a plurality of concentric circles and formed by several tens of first orifices 43 having a diameter of about 0.2 mm. A space 45 is provided in the back of the first orifices 43. Air is fed to the spaces 45 from an air source (not shown) via a first air passage 44. The air is released from the first orifices 43. In this way, the floatation mechanism 41 is a mechanism for floating via air pressure (hereinafter, this will be referred to as an air floatation mechanism).

In the air floatation mechanism 41, if air having a pressure of 5 kgf/cm² is fed to the space 45 (arrow D1), the workpiece 101 is pushed up in the direction of arrow D2. Simultaneously, the distance (gap) g between the bottom surface of the workpiece 101 and the top surface of the support 46 is corrected by a static pressure reduction effect due to a high speed flow generated by the combination of the air floatation mechanism 41 and the suction mechanism 42 to be explained below. For example, consider a case in which the interval in the XY directions of the air floatation mechanisms 41 is 300 mm, and the workpiece 101 is a glass having a size of 300 mm×1100 mm and a thickness of 5 mm. In this case, the distance g between the bottom surface of the workpiece 101 and the top surface of the support 46 can be maintained at 0.2 to 0.3 mm.

The suction mechanism 42 is positioned on the outer periphery of the array of the first orifices 43 of the air floatation mechanism 41. The suction mechanism 42 includes an annular groove 48 and a second air passage 47 formed concentrically, and is connected to a vacuum source (not shown). By drawing air via the second air passage 47 (arrow D3), the workpiece 101 can be sucked (arrow D4). In this way, the floating position of the workpiece 101 is stabilized to a position at which the suction force by drawing air through the groove 48 and the lifting force by blowing air through the orifices 43 balance each other out. For example, if the air supply passage 44 between the bottom surface of the first workpiece 101 and the top surface of the support 46 is connected with the suction mechanism 42 at a negative pressure of 0.3 kgf/cm², for example, the floating distance g of the workpiece 101 from the support 46 can be maintained at a fixed distance (for example, 0.2 mm) apart. Further, a workpiece warps within ±1.0 mm can be corrected by the workpiece-underside support mechanism 4. Thereby, changes in height of the workpiece surface can be suppressed to a range of ±0.05 mm. Therefore, high quality machining for forming a uniform groove width can be carried out.

The reason that the workpiece warps within ±1.0 mm can be corrected, and thereby changes in height of the workpiece surface can be suppressed to a range of ±0.05 mm, is that the suction force by drawing air through the groove 48 and the lifting force by blowing air through the orifices 43 balance each other out. Thereby, the forces act on the workpiece to make it flat. Further, the distance g is stably maintained by the static pressure reduction effect due to a high speed flow generated by the combination with the suction mechanism 42.

2.2 Modified Embodiment 1

FIG. 4 is a view showing a modified embodiment 1, which is one modified embodiment of the workpiece-underside support mechanism 4 shown in FIG. 3. FIG. 4(a) is a plan view of the main parts, and FIG. 4(b) is a cross-sectional view.

In the modified embodiment 1, the groove 48 in FIG. 3 is substituted with an array of second orifices 482 having a small diameter. The array of second orifices 482 is formed concentrically with the array of first orifices 43 and arranged on the outer periphery of the array of first orifices 43. The array of second orifices 482 is in communication with a groove space 481 within the support 46. The groove space 481 is in communication with the second air passage 47. In this embodiment, the diameter of the second orifices is preferably approximately 1.5 mm, for example. By this structure, the modified embodiment 1 can lift and hold the workpiece 101 similar to the embodiment shown in FIG. 3.

The other members which have not been particularly explained have the same configuration and equivalent function to those in the workpiece-underside support mechanism 4 shown in FIG. 3.

2.3 Modified Embodiment 2

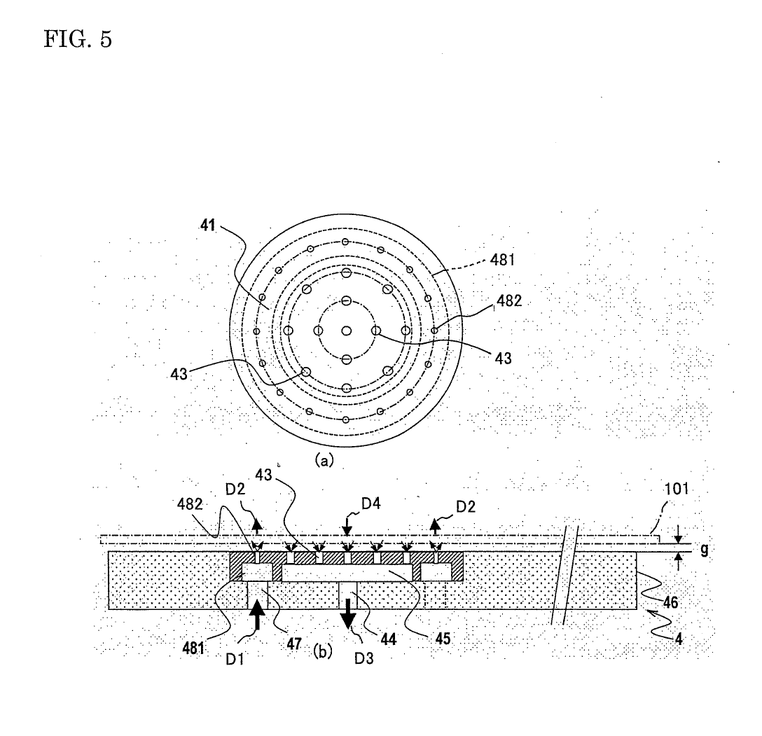

FIG. 5 is a view showing a modified embodiment 2 of the workpiece-underside support mechanism 4 shown in FIG. 3. FIG. 5(a) is a plan view of the main parts, and FIG. 5(b) is a cross-sectional view.

In the modified embodiment 2, the functions of the first and second air passages 44 and 47 in the modified embodiment shown in FIG. 4 are reversed. In other words, in the modified embodiment 2, the first air passage 44 is provided on the suction side, whereas the second air passage 47 is provided on the supply side. In the modified embodiment 2, the diameter of the second orifices 482 is preferably about 0.2 mm, and the diameter of the first orifices 43 is preferably approximately 1.5 mm. Thereby, the second orifices 482 are used for floating the workpiece 101. On the other hand, the first orifices 43 are used for sucking the workpiece 101.

In the workpiece-underside support mechanism 4 shown in FIG. 3, a suction force cannot be immediately obtained even if the workpiece 101 reaches the groove 48, because the opening area of the groove 48 is large. The suction force sharply increases from the time at which the opening is covered. In contrast, in the workpiece-underside support mechanisms 4 of the modified embodiments 1 and 2 shown in FIGS. 4 and 5, when the workpiece 101 reaches the orifices having a sucking function, the number of orifices facing the workpiece increases in accordance with the position of the workpiece 101. Therefore, the suction force gradually increases. Further, when the workpiece goes away from the orifices having a suction function, the suction force gradually decreases. Thereby, compared to the embodiment in FIG. 3, since changes in the suction force are reduced, the suction force can be averaged. Therefore, the suction force can be stabilized during movement of the workpiece 101.

The other members which have not been particularly explained have the same configuration and equivalent function to those in the workpiece-underside support mechanism 4 shown in FIG. 3.

2.4 Modified Embodiment 3

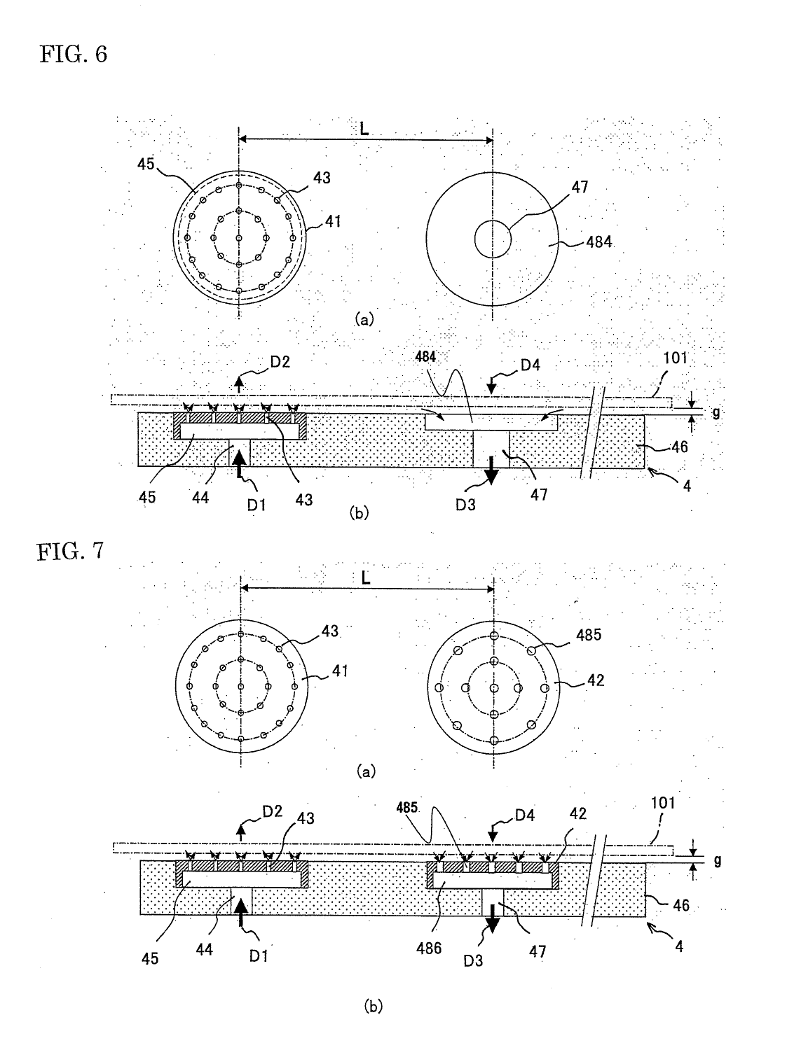

FIG. 6 is a view showing a modified embodiment 3 of the workpiece-underside support mechanism 4 shown in FIG. 3. FIG. 6(a) is a plan view of the main parts, and FIG. 6(b) is a cross-sectional view.

In the embodiments shown in FIGS. 3 to 5, the air floatation mechanism 41 and the suction mechanism 42 are arranged concentrically. However, the air floatation mechanism 41 and the suction mechanism 42 can be constituted as a separated structure and arranged alternately at each distance L. Further, as shown in FIG. 6, a circular cavity 484 may be used instead of the groove 48.

The other members which have not been particularly explained have the same configuration and equivalent function to those in the workpiece-underside support mechanism 4 shown in FIG. 3.

2.5 Modified Embodiment 4

FIG. 7 is a view showing a modified embodiment 4 of the workpiece-underside support mechanism 4 shown in FIG. 3. FIG. 7(a) is a plan view of the main parts, and FIG. 7(b) is a cross-sectional view.

In the case of the modified embodiment 3, since the area of the cavity 484 is large similar to the workpiece-underside support mechanism 4 shown in FIG. 3, the sucking force changes rapidly. Thus, in the modified embodiment 4 shown in FIG. 7, an array of third orifices 485 is arranged concentrically as an air inlet. The array of third orifices 485 is in communication with a space 486 within the support 46. The space 486 is in communication with the second air passage 47. Thereby, compared to the modified embodiment 3, since rapid pressure changes can be reduced, the pressure can be averaged.

In all of the workpiece-underside support mechanisms of the basic configuration and the modified embodiments 1 to 4 explained above with reference to FIGS. 3 to 7, the air pressure fed to the air floatation mechanism 41 may be changed according to the disposal location. Alternatively, in addition to changing the air pressure, the diameter of the first to third orifices 43, 482, and 485 can be changed according to the disposal location. Thereby, the floating distance g of the workpiece 101 from the top surface of the support 46 can be controlled. Thus, for example, if the distance g is controlled so that it is at a maximum at the machining portion (at the center line CL), there will be almost no effect from warping even if the workpiece 101 warps 1 mm or more. Therefore, the machining precision can be enhanced.

### 3. Workpiece Clamp Mechanism

The workpiece 101 is supported so that it is movable in the Z direction in a state in which it is floated on an air cushion. Therefore, it is necessary to hold the workpiece in this state. Thus, in the present embodiment, a workpiece side clamp mechanism 6, a workpiece front end surface clamp mechanism 7, and a workpiece rear end surface clamp mechanism 8 are provided as a workpiece clamp mechanism

3.1 Workpiece Side Clamp Mechanism

3.1.1 Basic Configuration

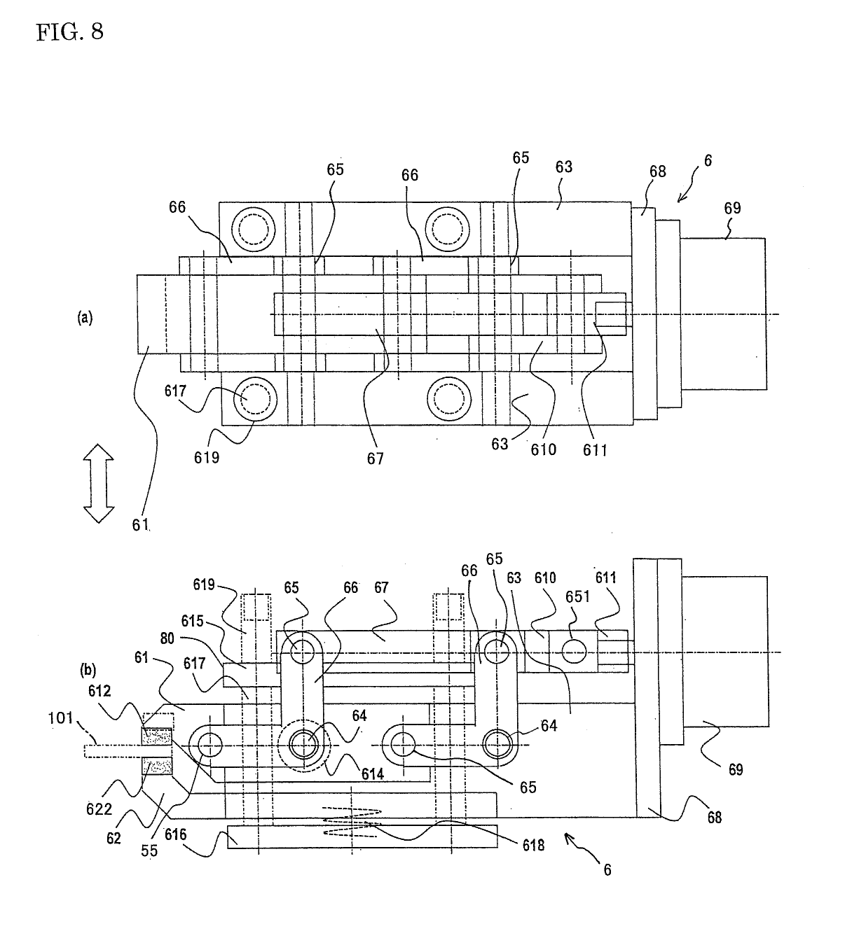

FIG. 8 is a view showing the details of the workpiece side clamp mechanism 6. FIG. 8(a) is a plan view, and FIG. 8(b) is a side view.

In FIG. 8, the workpiece side clamp mechanism 6 is comprised of upper and lower clamp arms 61 and 62, link supports 63, clamp pins 64 and 65, links 66 and 67, a connecting plate 68, a drive cylinder 69, and the like.

The link supports 63 and the drive cylinder 69 are connected with the connecting plate 68 between. The link supports 63 are provided in a pair (an upper and lower in FIG. 8(a)) in a parallel manner in the X direction. A link fitting 611 is connected to the piston rod of the drive cylinder 69 through the connecting plate 68. A pair of links 610 is rotatably held on a side surface of the link fitting 611 by a clamp pin 651. The link 67 and a pair of L-shaped links 66 are rotatably held on the inside of the pair of links 610 by a clamp pin 65. Another pair of links 66 is rotatably held on the other side of the link 67 by a clamp pin 65. The center parts of the four links 66 are rotatably supported by the clamp pins 64 on the link support 63. The other ends of the four links 66 are rotatably supported by clamp pins 55 on the upper clamp arm 61. The four links 66, the link 67, and the upper clamp arm 61 form a link mechanism. Therefore, the upper clamp arm 61 is lowered while keeping its horizontality, by moving the link fitting 611 toward the left in the drawing by operating the drive cylinder 69. The lower clamp arm 62 is fixed to the link support 63. The upper clamp arm 61 is prevented from interfering with the clamp pin 64 by a clearance hole 614 formed in the upper clamp arm 61.

The workpiece side clamp mechanism 6 explained above is supported so that it is movable in the vertical direction with a retaining device 80 comprised of an upper support 615, a lower support 616, and the link support 63, as well as four guide shafts 617 which pass through these in the vertical direction. A spring 618 supported by the lower support 616 supports the workpiece side clamp mechanism 6. The retaining device 80 is supported on the first X movement mechanism 1 by a support device (not shown). Thereby, the workpiece holding surface 622 of the lower clamp arm 62 is 0.5 mm lower relative to the bottom surface of the workpiece 101 installed into the device.

In the above configuration, when the drive cylinder 69 is activated, a workpiece holding surface 612 of the upper clamp arm 61 lowers while keeping its horizontality, and presses the workpiece 101 to the workpiece holding surface 622 of the lower clamp arm 62. Even if the workpiece 101 does not move in a downward direction, the workpiece 101 can be held, since the lower clamp arm 62 rises relatively. In other words, even if there is a deformation in the workpiece 101, the workpiece 101 can be securely held. Further, the vertical balanced load can be maintained not more than 1 kg by the spring 618. Therefore, the workpiece 101 does not deform. The workpiece 101 which is supported by the workpiece side clamp mechanism 6 is fixed in the X direction, and is supported to be movable in the Z direction. The spring 618 has a function of making the load applied to the workpiece 101 1 kg or less by receiving empty weight of the clamp mechanism 6. In this way, by balancing the load applied to the workpiece along the vertical direction at 1 kg or less, deformations or height variations of the workpiece 101 that occur when large forces act on the workpiece 101 can be prevented. Thus, the clamp mechanism including the spring 618 has a function of holding the workpiece while following it in the vertical direction.

3.1.2 Modified Embodiment

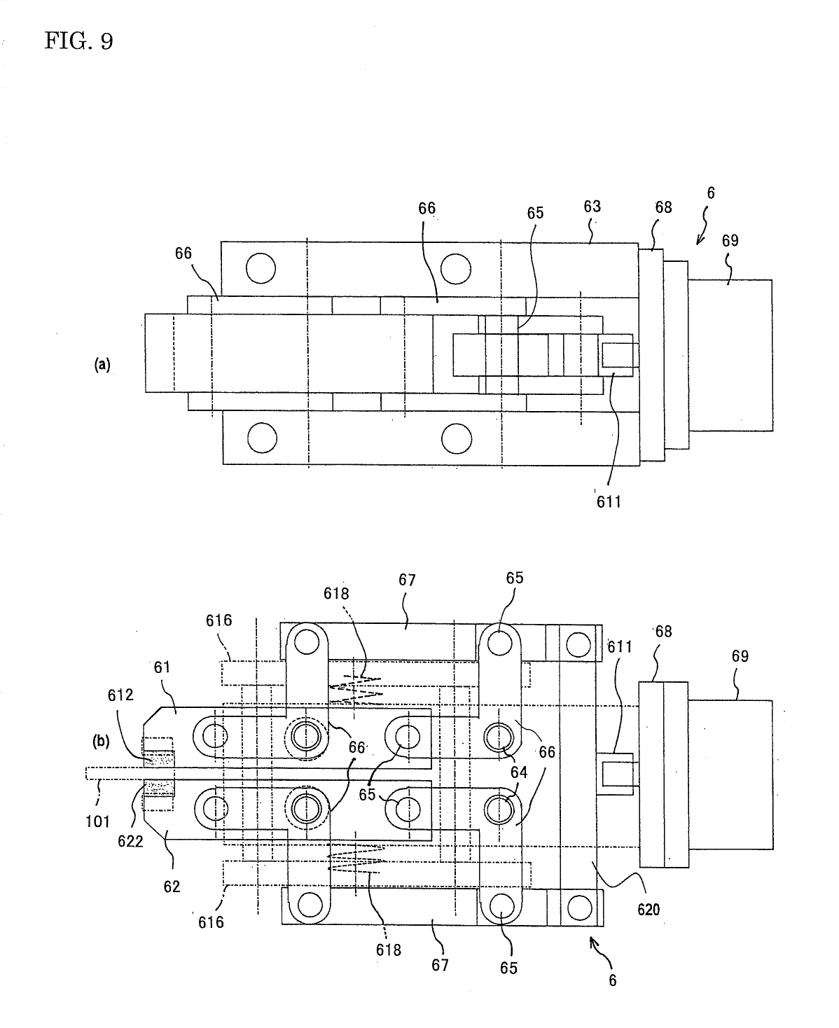

FIG. 9 is a view showing a modified embodiment of the workpiece side clamp mechanism 6 shown in FIG. 8. FIG. 9(a) is a plan view, and FIG. 9(b) is a side view.

In the workpiece side clamp mechanism 6 according to the modified embodiment shown in FIG. 9, not only the upper clamp arm 61, but also the lower clamp arm 62 can move up and down using the link mechanism shown in FIG. 8. In this modified embodiment, the link fitting 611 is constituted integrally with a connecting member 620 for driving the upper and lower links 66 and 67 simultaneously. Thereby, the link fitting 611 transmits the reciprocal movement of the drive cylinder 69 to the upper and lower links 67. Thereby, the clamping action and clamping release action of the upper and lower clamp arms 61 and 62 become possible. These actions are substantially the same as the actions shown using FIG. 8. Therefore, members which are identical to those shown in FIG. 8 are given the same reference numerals and explanations thereof are omitted.

In the case of this modified embodiment, the position of the abutting surface of the lower clamp arm 62 relative to the bottom surface of the workpiece 101 during the installation can be lowered compared to the case using the embodiment in FIG. 8. In other words, a large gap can be provided between both surfaces.

3.2 Workpiece Front End Surface Clamp Mechanism

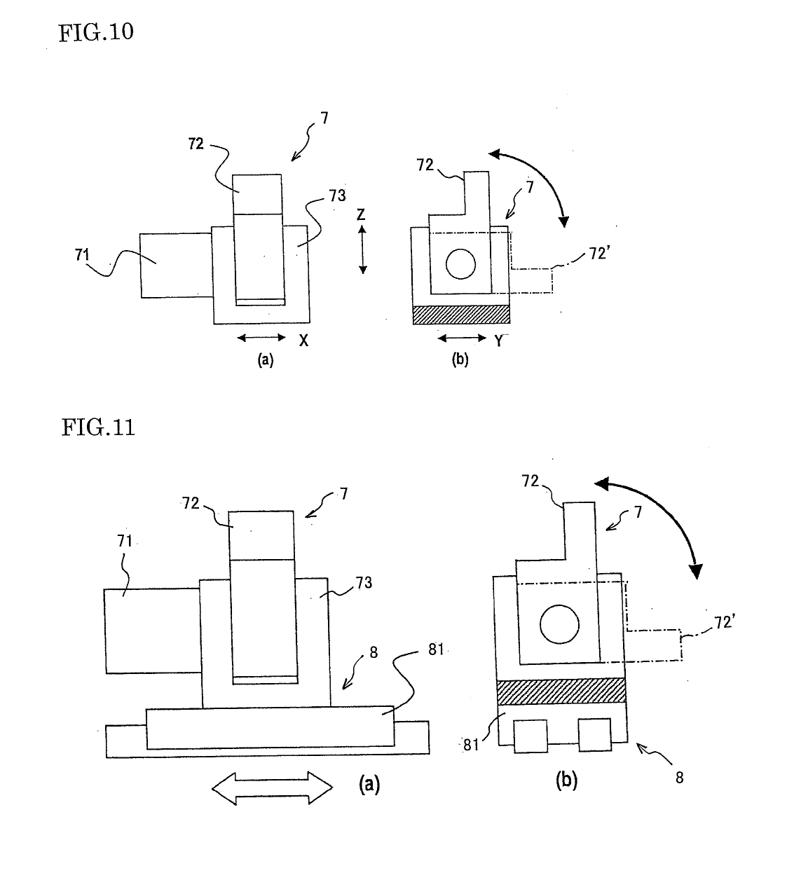

FIG. 10 is a view showing the details of a workpiece front end surface clamp mechanism 7. FIG. 10(a) is a front view, and FIG. 10(b) is a cross-sectional side view.

A rotary cylinder 71 rotates a clamp arm 72 in the direction of the arrow in FIG. 10 via an arm rotating mechanism 73. The front end surface of the workpiece 101 is then positioned in the X direction at the position of the clamp arm 72′ shown by the dashed dotted line.

3.3 Workpiece Rear End Surface Clamp Mechanism

FIG. 11 is a view showing the details of a workpiece rear end surface clamp mechanism 8. FIG. 11(a) is a front view, and FIG. 11(b) is a cross-sectional side view.

The workpiece rear end surface clamp mechanism 8 has the same as the workpiece front end surface clamp mechanism 7 and a movement mechanism 81 which carries the workpiece front end surface clamp mechanism 7 and moves the workpiece front end surface clamp mechanism 7 in the X direction. The workpiece rear end surface clamp mechanism 8 determines the position of the rear end surface of the workpiece 101 in the X direction.

3.4 Arrangement

In the thin-film layer machining apparatus main body SA, the clamp mechanisms explained above can have not only the arrangement shown in FIG. 2, but can also be arranged in various ways. In the present embodiment, for example, an arrangement as described below is utilized.

3.4.1 First Arrangement Example

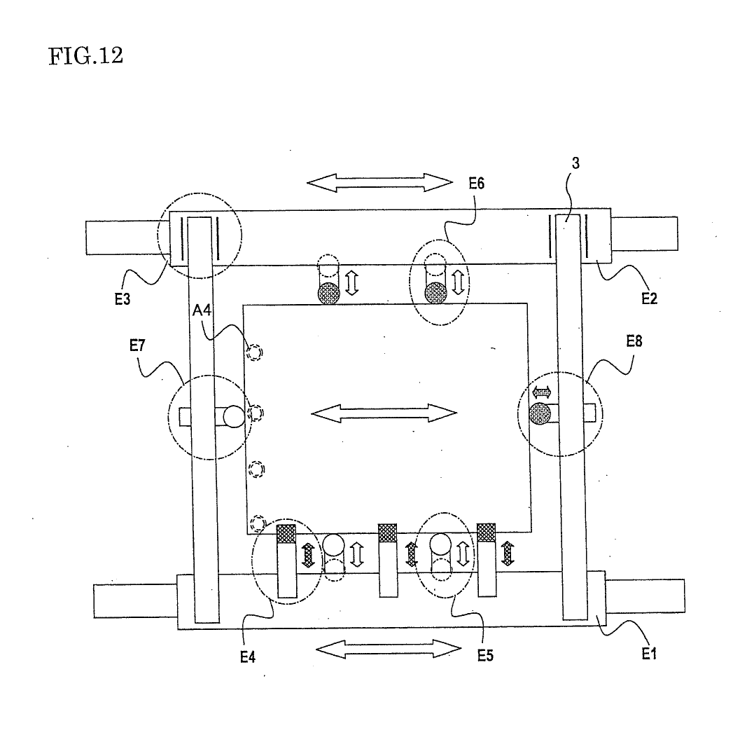

FIG. 12 is a plan view showing a first arrangement example of the clamp mechanisms in the present embodiment. FIG. 12 corresponds to FIG. 2. The air floatation mechanism, the suction mechanism (vacuum suction mechanism), and the like are omitted from this drawing.

In FIG. 12, the machining apparatus includes a first X driving mechanism E1, a second X driving mechanism E2 (when the workpiece size is small, a follower mechanism without a driving part is also possible), a slide mechanism E3, a workpiece side clamp mechanism E4 including a mechanism for movement in the arrow direction, a workpiece side positioning roller mechanism E5 including a mechanism for movement in the arrow direction, a workpiece side pressure roller mechanism E6 including a mechanism for movement in the arrow direction, a workpiece front end positioning mechanism E7 including a mechanism for movement in the arrow direction, and a workpiece rear end positioning mechanism E8 including a mechanism for movement in the arrow direction. The double circles in FIG. 12 show the positions of the respective machining heads A4.

The first arrangement example is for a large workpiece (for example, 2600 mm×2200 mm). Thus, the workpiece front end positioning mechanism E7 and the workpiece rear end positioning mechanism E8 are arranged at a center position in the Y direction.

In the case of this arrangement example, when the side surface clamping by the side clamp mechanism E4 has been completed, only the pressure roller E5 is retracted. Machining is carried out while the workpiece side pressure roller mechanism E6, the workpiece front end positioning mechanism E7 and the workpiece rear end positioning mechanism E8 are pressing.

3.4.2 Second Arrangement Example

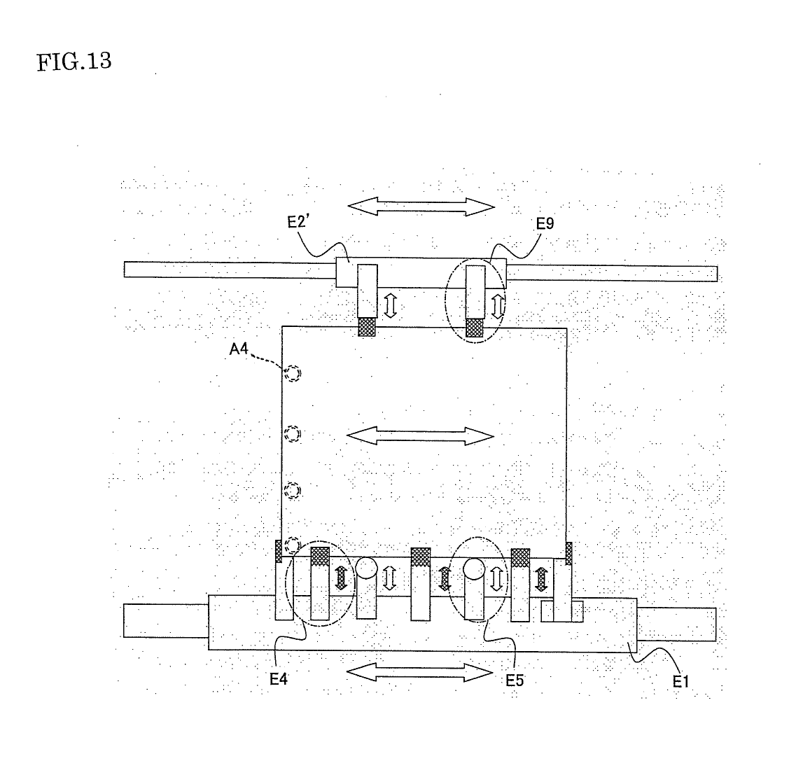

FIG. 13 is a plan view showing a second arrangement example, which is a modified embodiment of the first arrangement example of the clamp mechanisms shown in FIG. 12.

In this arrangement example, the workpiece side pressure roller E6 shown in FIG. 12 is replaced with a workpiece side clamp mechanism E9, and the X driving mechanism E2 is replaced with a follower mechanism E2′. Further, the workpiece front end positioning mechanism E7, the workpiece rear end positioning mechanism E8, and the slide mechanism E3 are eliminated. The other members are the same as the members in the first arrangement example shown in FIG. 12.

By constituting the arrangement in this way, the structure of the clamp mechanisms is simplified. Further, the clamps can be stabilized on the workpiece. Therefore, clamping imperfections do not easily occur.

3.4.3 Third Arrangement Example

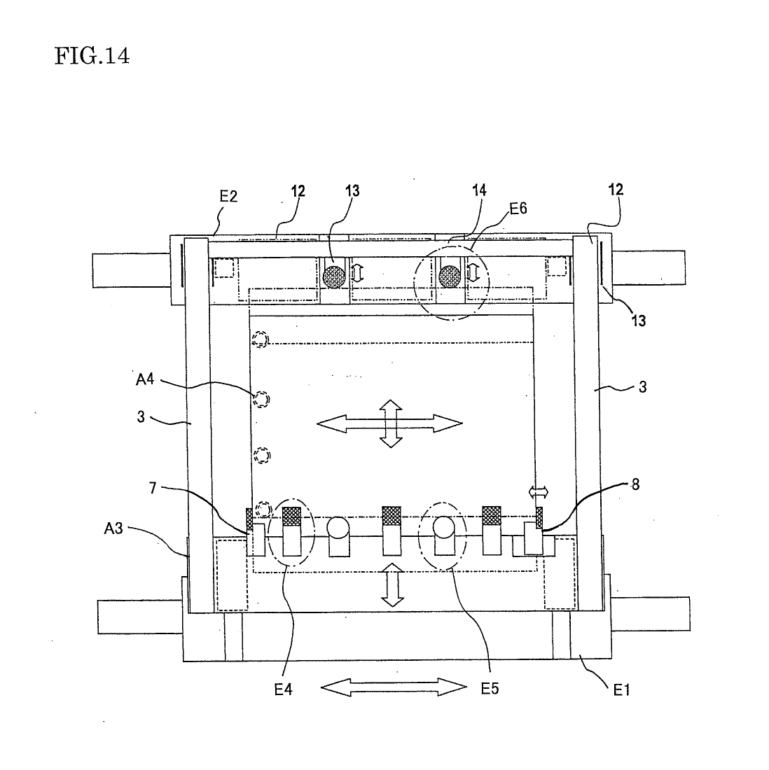

FIG. 14 is a plan view showing a third arrangement example of the clamp mechanisms.

The third arrangement example is for a large (or medium) workpiece (2600 mm×2200 mm) A Y-axis direction movement mechanism is disposed on the first X driving mechanism E1. On the movement part thereof, the workpiece side clamp mechanism E4 and the workpiece side pressure roller mechanism E5 are mounted. Thereby, the workpiece is moved in the XY directions. Thus, a predetermined range on the workpiece 101 can be machined without moving the machining head A4. Further, an air floatation and suction mechanism 12 is provided on the upper surface of the second X driving mechanism E2. Further, a groove for clearance 13 which prevents interference of the pressure roller E6 is formed on the top surface. In addition, the end portions of the connecting plates 3 are connected by a connecting plate 14. By using the side pressure roller mechanism E6 on the connecting plate 14, the workpiece can be pressed even during machining.

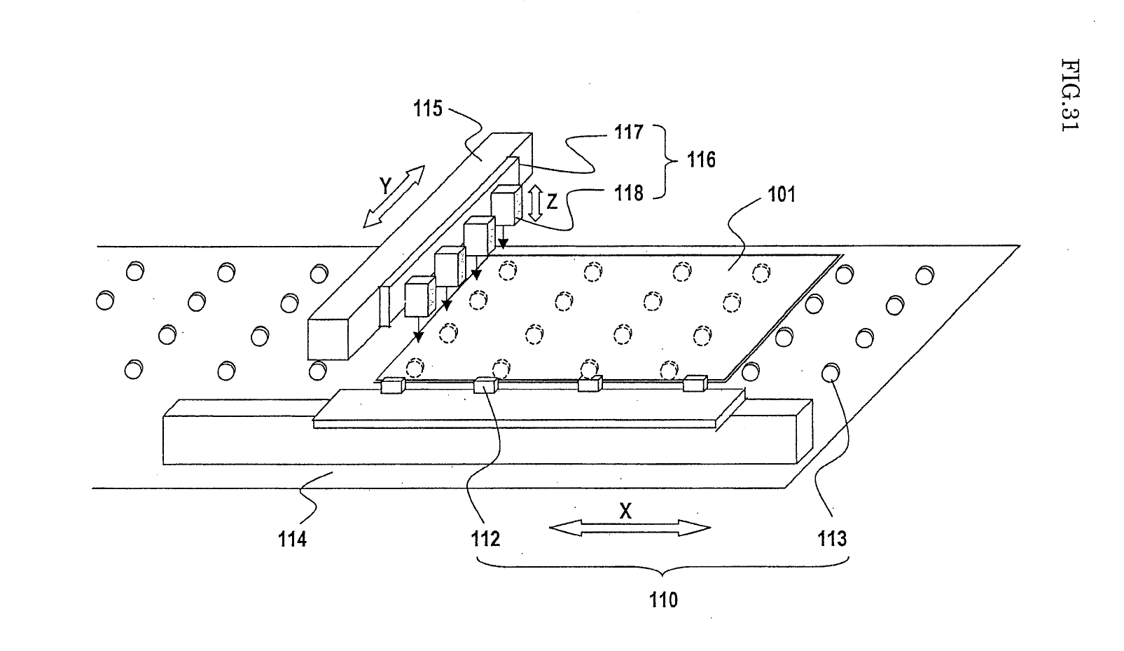

Until this point, the present invention has been explained with regard to a case in which it is applied to an apparatus for machining the first to third line grooves P1 to P3 as in FIG. 30. However, by arranging the mechanisms E4 to E7 as described below, the present invention can also be applied to a workpiece periphery machining apparatus which removes a range of 10 to 12 mm from the outer periphery of the workpiece 101 by a high power laser having a wavelength of 1064 nm in a removed portion machining step.

3.4.4 Fourth Arrangement Example

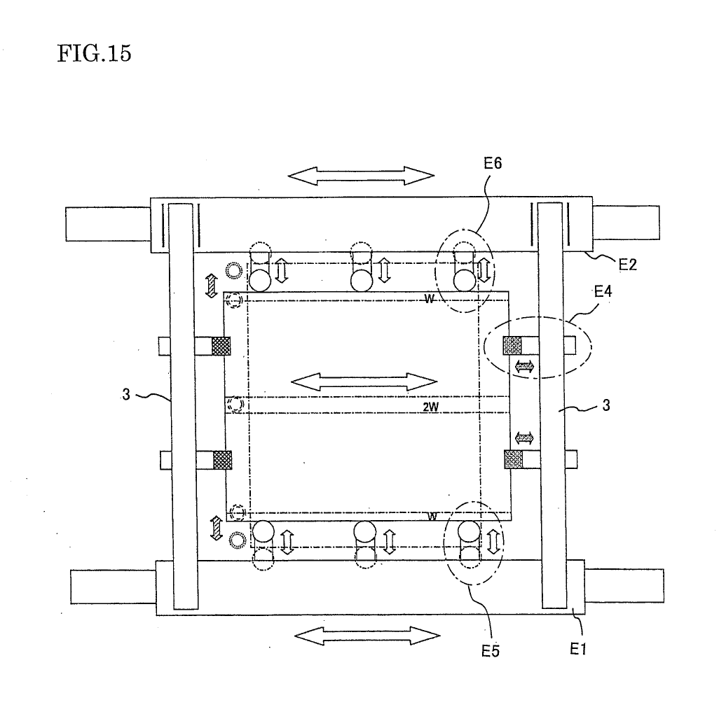

FIG. 15 is a plan view showing a fourth arrangement example of the clamp mechanisms.

The fourth arrangement example is for a large workpiece (2600 mm×2200 mm). In this arrangement example, a mechanism which moves the workpiece side clamp mechanism E4 in the arrow direction is disposed on two connecting plates 3. The position of the workpiece in the Y direction is determined by the side positioning roller mechanism E5 and the side pressure roller mechanism E6 disposed on the bed. After the workpiece is clamped by the clamp mechanism E4, the side positioning roller mechanism E5 and the side pressure roller mechanism E6 are retracted. Subsequently, the workpiece is machined. After the longer edge side of the workpiece is machined, the workpiece is rotated by 90° on an air cushion at a position in the left side of the center line CL (FIG. 2). Subsequently, the shorter edge side of the workpiece is machined. After the shorter edge side is machined, the workpiece is returned to its original position by rotating by 90°, and then the workpiece is discharged. The other members are constituted in the same way as those of the first arrangement example shown in FIG. 12.

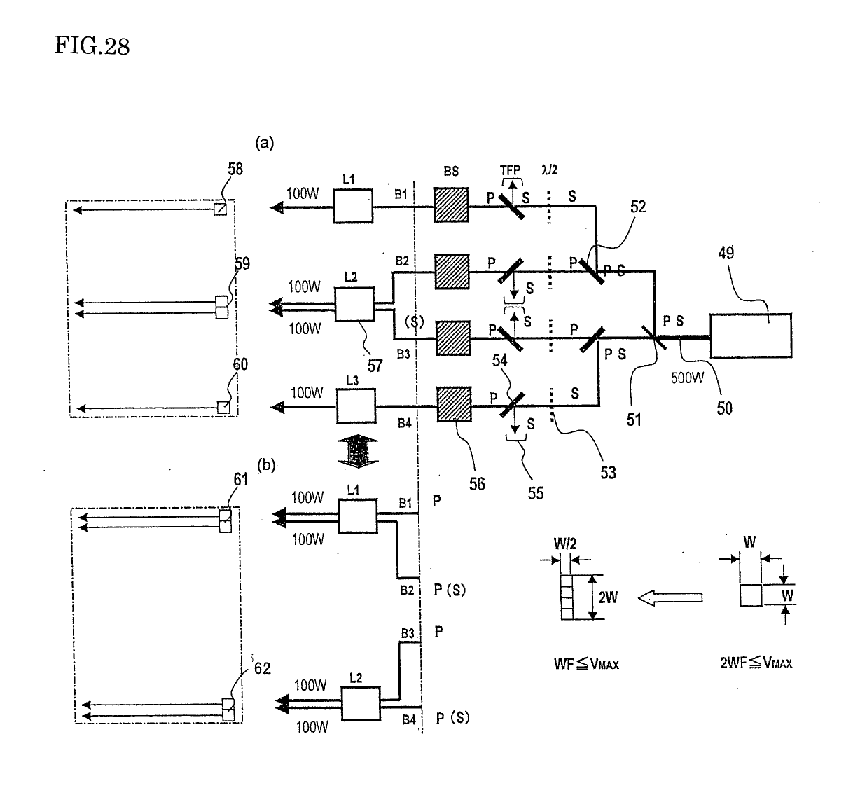

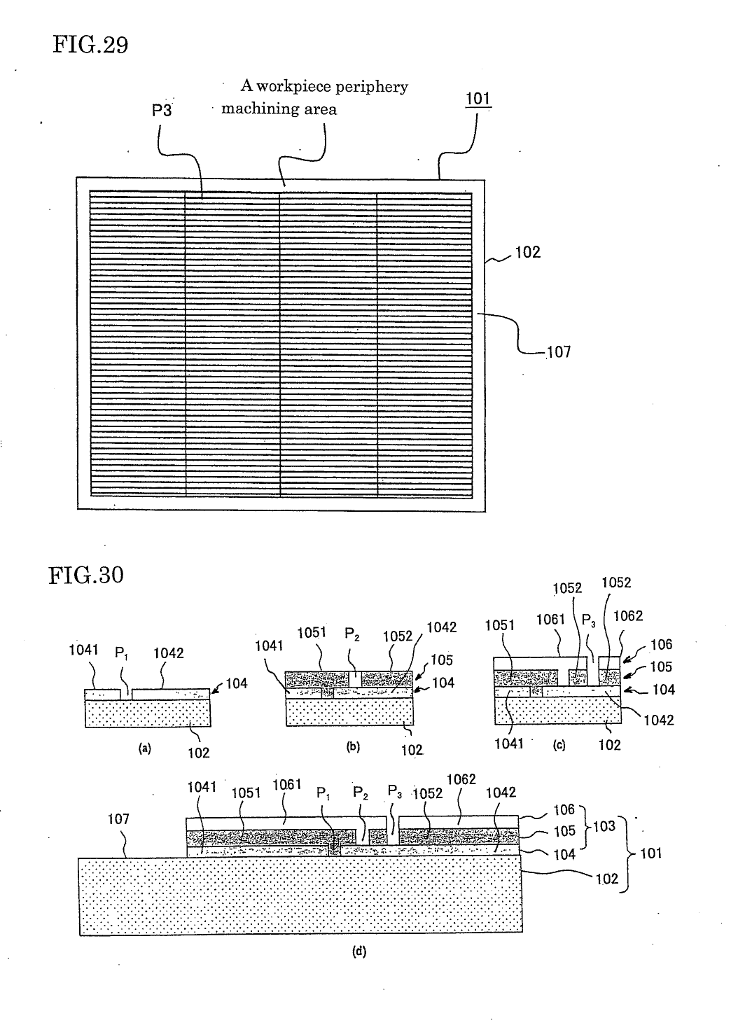

In the present arrangement example, both sides can be machined in one spot and the center can be machined in two spots by using the laser head shown in FIG. 28(a) to be explained later.

3.4.5 Fifth Arrangement Example

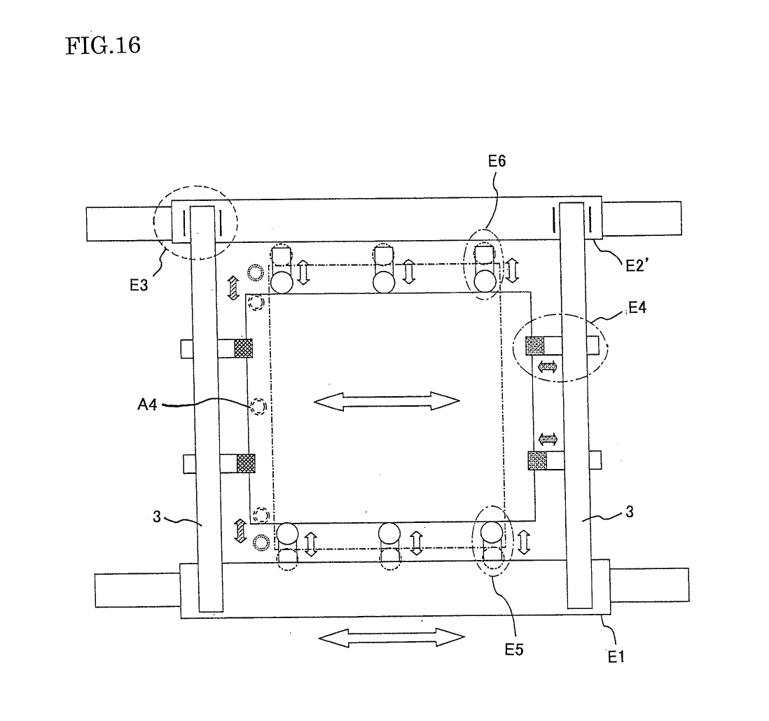

FIG. 16 is a plan view showing a fifth arrangement example of the clamp mechanisms.

The fifth arrangement example is for a medium workpiece (1400 mm×1100 mm). The workpiece side clamp mechanism E4 explained above is disposed with a vertical movement mechanism and a front-back movement mechanism on the two connecting plates 3, which are connected to the follower mechanism E2′ to the slide mechanism E3. The other members are constituted in the same way as those of the first arrangement example shown in FIG. 12.

By arranging as explained in this arrangement example, the configuration shown in FIG. 28(b) to be explained later can be used as the laser head. Therefore, the both sides can be machined simultaneously.

3.4.6 Sixth Arrangement Example

FIG. 17 is a plan view showing a sixth arrangement example of the clamp mechanisms.

The sixth arrangement example is for a medium or small workpiece (1400 mm×1100 mm or less). In this arrangement example, the second X driving mechanism E2 is not used. Instead, flat air bearings E21 are disposed on the end portions of the connecting plates 3. The flat surface air bearings E21 are constituted to slide on the surface of a flat guide. In addition, a workpiece rear end positioning mechanism 15 is disposed on the first X driving mechanism E1. In this arrangement example, by moving the connecting plate on the rear side in the X direction, workpieces of various sizes can be adjusted. The other members are constituted in the same way as those of the first arrangement example shown in FIG. 12.

By arranging as explained in this arrangement example, the configuration shown in FIG. 28(b) to be explained later can be used as the laser head. Therefore, both sides can be machined simultaneously.

### 4. Dust Collector for Line Groove Machining

4.1 Embodiment of First Dust Collector

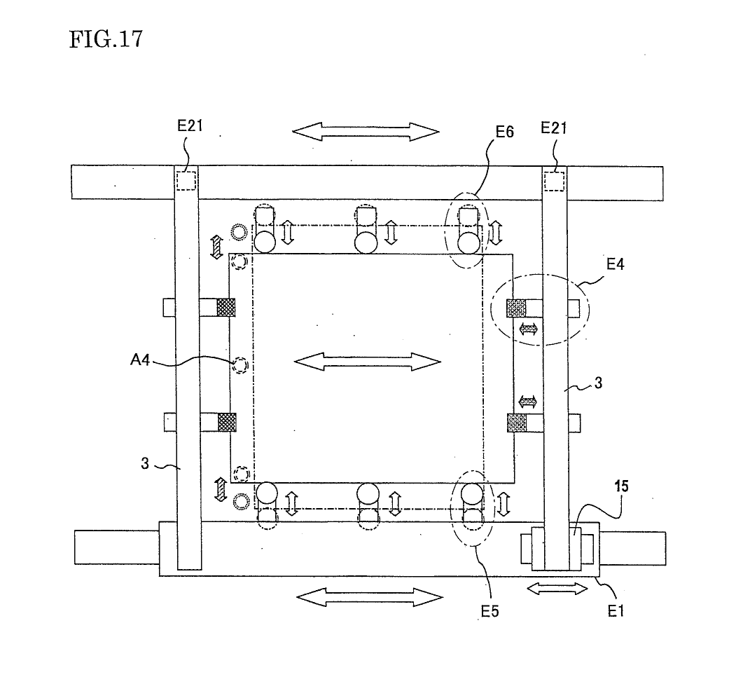

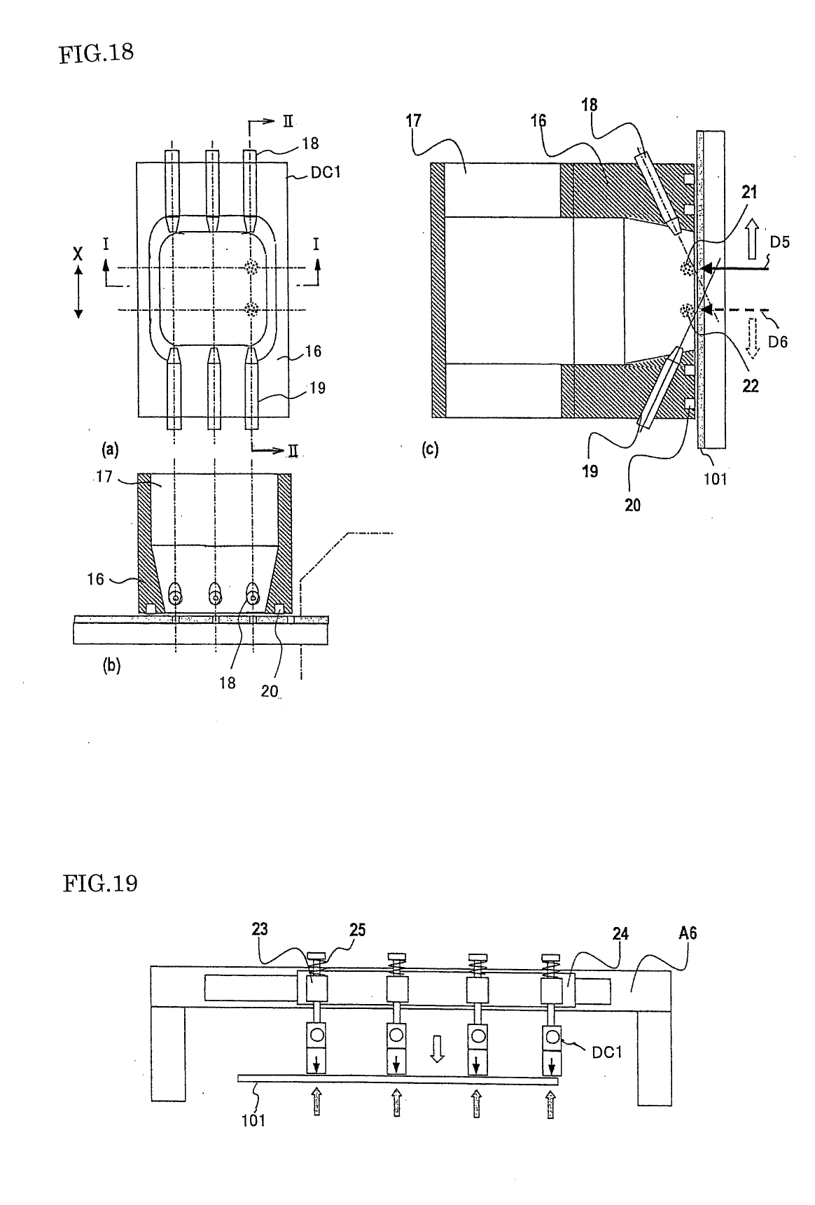

FIG. 18 is a view for explaining a first dust collector (hereinafter referred to as the “dust collector DC1”) for machining the line grooves according to the embodiment of the present invention. FIG. 18(a) is a plan view, FIG. 18(b) is a cross-sectional view along line I-I of FIG. 18(a), and FIG. 18(c) is a cross-sectional view along line II-II of FIG. 18(a).

The dust collector DC1 includes a dust collection chamber 16, a dust collection duct 17, nozzles 18 and 19, and an air floatation groove 20. The plurality of nozzles 18 and 19 (in FIG. 18, there are 3 of each) are disposed in the dust collection chamber 16 so that they are facing each other in the X direction. The dust collection chamber 16 is connected to the dust collection duct 17. The nozzles 18 and 19 deliver a cooling medium such as air, mist, or liquid (herein, water or sprayed water). The air floatation groove 20, which is formed on the bottom surface (the surface facing the workpiece 101) of the dust collection chamber 16, is connected to a compressed air source (not shown). As will be explained later, the dust collector DC1 is pressed against the workpiece 101 with a preset pressure.

Air delivered from the air floatation groove 20 forms a layer of air between the workpiece 101 and the dust collector DC1. The air layer floats the dust collector DC1. The workpiece 101 is biased in the Z direction. As a result, warps of the workpiece 101 are corrected. Thereby, height variations of the surface of the workpiece can be minimized.

In FIG. 18(c), if the workpiece 101 is moved in the direction of arrow D5 shown by a solid line, the cooling medium is delivered from the nozzle 18 to a machining portion 21. If the workpiece 101 is moved in the direction of arrow D6 shown by a dashed line, the cooling medium is delivered from the nozzle 19 to a machining portion 22. In other words, the nozzle used is switched so that the cooling medium is delivered towards the direction in which the workpiece is proceeding. As a result, debris generated by the machining are cooled down by the cooling medium and carried to a not-yet-machined portion. Therefore, the debris can be easily removed by an air blow or the like after machining since they adhere only weakly to the surface of the workpiece 101.

FIG. 19 is a side view showing the main parts of a column A6 provided with the dust collector DC1.

In FIG. 19, air cylinders 23 are fixed on a carriage 24. The carriage 24 is movable in the Y direction on the column A6. The dust collector DC1 is fixed to a piston rod of the air cylinder 23. The piston rod is usually elastically biased by a spring 25 toward the upward direction in FIG. 19. During machining, the air cylinder 23 pushes the dust collector DC1 toward the workpiece 101 with a preset pressure. Therefore, warps of the workpiece are corrected. The spring 25 prevents the dust collector DC1 from dropping onto the workpiece 101 if the air supplied to the air cylinders 23 is stopped.

Air flows at high speed from the air floatation groove 20 toward the inside of the dust collection chamber 16. Therefore, the cooling medium, even in case of using a mist or water as the cooling medium, is collected from the dust collection duct 17 even if the workpiece 101 is warped. Thus, there are no leaks of the cooling medium to the outside of the dust collection chamber 16. Further, if the workpiece 101 is mounted on an XY table, the air cylinders 23 can be directly fixed to the column A6.

4.2 Embodiment of Second Dust Collector

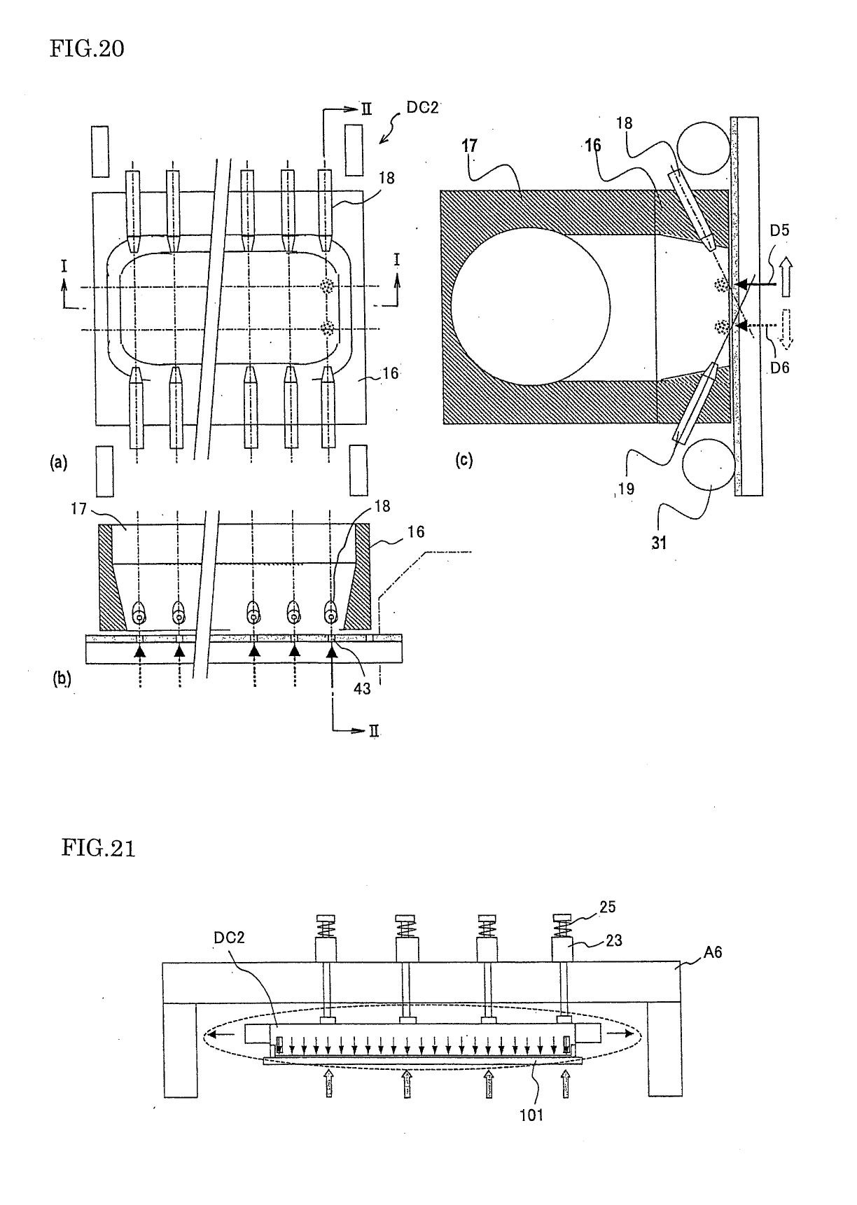

FIG. 20 is a plan view for explaining a second dust collector (hereinafter referred to as the “dust collector DC2”) for machining the line grooves according to the embodiment of the present invention. FIG. 20(a) is a plan view, FIG. 20(b) is a cross-sectional view along line I-I of FIG. 20(a), and FIG. 20(c) is a cross-sectional view along line II-II of FIG. 20(a). Members which are identical to those shown in FIGS. 18 and 19 are given the same reference numerals and explanations thereof are omitted.

Guide rollers 31 are supported in a rotatable manner on the side surface in the X direction of the dust collection chamber 16. The position of the guide rollers 31 in the Z direction is determined such that the underside of the dust collection chamber 16 can maintain a spacing (approximately 0.5 mm) from the top surface of the workpiece 101. The position of the guide rollers 31 in the Y direction is determined so that the line grooves P1 to P3 do not overlap with each other.

FIG. 21 is a side view showing the main parts of the column A6 equipped with the dust collector DC2. In FIG. 21, the length of the dust collector DC2 in the Y direction is approximately the same as the width of the workpiece 101. Therefore, in the configuration of FIG. 21, the dust collector DC2 is pressed by four air cylinders 23. In the dust collector DC2, the air cylinders 23 are fixed to the column A6. This is because it is not necessary for the cylinders to move in the Y direction.

4.3 Embodiment of Third Dust Collector

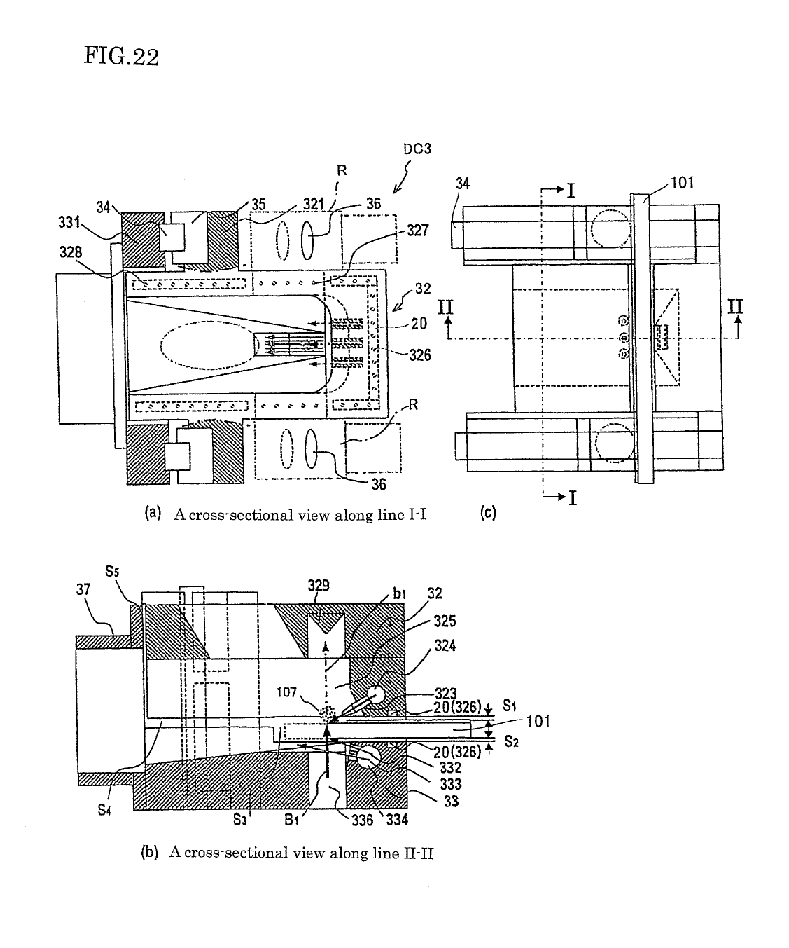

FIG. 22 is an explanatory view of a third dust collector (hereinafter referred to as the “dust collector DC3”) used in the case of forming a removed portion 107 around the periphery of the workpiece. FIG. 22(c) is a front view, FIG. 22(a) is a cross-sectional view along line I-I of FIG. 22(c), and FIG. 22(b) is a cross-sectional view along line II-II of FIG. 22(c).

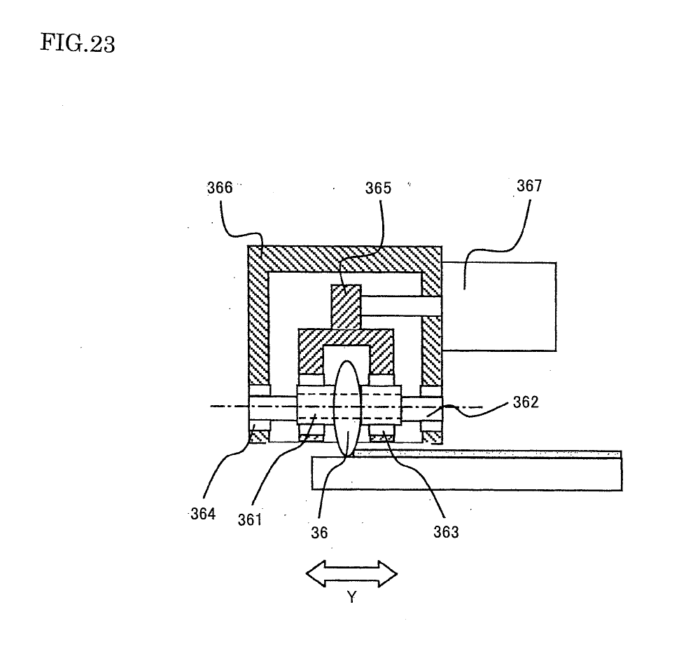

In FIG. 22, an upper dust collection chamber (upper chamber) 32 includes a plurality of nozzles 323 (three in the case of FIG. 22) similar to the dust collection chamber 16. The cooling medium, which is supplied through a passage 324, is delivered toward the workpiece 101 at a preset pressure from the nozzles 323. The delivered cooling medium is discharged from a dust collection duct 37 through a cavity 325. On the bottom surface, in addition to grooved air blowing outlets 326 and 328 and the floatation groove 20, a plurality of circular air blowing outlets 327 are provided. The inside of the upper dust collection chamber 32 is barriered off from the outside by the air. The nozzles 323 are disposed on the upper dust collection chamber 32 so that their blowing outlets are facing the Y direction. The nozzles 323 deliver cooling medium similar to the nozzles 18 and 19. A machining laser beam B1 is incident on the workpiece 101. Upon passing through the workpiece 101, a laser beam b1 is incident on the upper dust collection chamber 32. As will be explained below, a beam damper 329 which absorbs the laser beam b1 is disposed at the irradiation position for the laser beam b1 in the upper dust collection chamber 32. Flanges 321 are provided on both side surfaces in the X direction of the upper dust collection chamber 32. A pair of bearings (linear guide devices) 35 are fixed to the flanges 321. Guide roller units R are also disposed on both side surfaces in the X direction of the upper dust collection chamber 32. FIG. 23 is a vertical cross-sectional view of the guide roller units R.

As shown in FIG. 23, the guide roller unit R is basically comprised of a holder 366, an inner housing 365, a slider 361, a shaft 362, and a guide roller 36. The holder 366 is fixed to the dust collection chamber 16. The guide roller 36 is integrated with the ball spline slider 361. The shaft 362 is rotatably supported on the holder 366 by a bearing 364. The slider 361 is rotatably supported on the inner housing 365 by a bearing 363. Further, the slider 361 is supported so that it is movable in the axial direction relative to the shaft 362. The inner housing 365 is fixed to a cylinder rod of a cylinder 367 fixed to the holder 366.

In the above-described configuration, the guide roller 36 moves in the Y direction by moving the cylinder rod. Thereby, the workpiece can be positioned. Here, it is practical to make the movement stroke of the guide roller 36 larger than ½ of the machining width of the removed portion 107. That is, for example, the guide roller 36 is positioned at the center of the machined width to begin the machining. When the machining reaches the center position, the guide roller 36 is moved slightly in front of the machining completion position. In this way, the thin-film layer of the workpiece 101 will not be damaged by the guide roller 36. Further, a structure which disposes the guide roller 36 (inner housing 365) at a desired position by a motor can also be achieved. The position of the guide roller 36 in the Z direction is determined so that the lower end of the guide roller 36 projects from the lower end of the upper dust collection chamber 32 by a distance of S1 (for example, 0.5 mm).

As shown in FIG. 22(b), a lower dust collection chamber (lower chamber) 33 has an L-shape. Flanges 331 are provided on both side surfaces in the X direction of this chamber. Tracks 34 which engage with bearings (linear guide devices) 35 are fixed to the flanges 331. The lower dust collection chamber 33 covers the end of the workpiece 101 by combining with the upper dust collection chamber 32. A through opening 336 for transmitting an incident machining laser beam B1 is provided on the bottom surface of the lower dust collection chamber 33. Further, the air floatation groove 20 is provided on the side of the lower dust collection chamber 33 facing the workpiece 101.

In order to prevent the cooling medium from leaking to the outside from the opening 336, rectangular air blow outlets 332 and 333, having a long side along the X direction, are provided. The air blow outlets 332 and 333 are connected to a compressed air source (not shown) via a passage 334. Further, an air blow outlet is also provided at a position facing an air blow outlet 327 on the upper surface of the lower dust collection chamber 33. The lower dust collection chamber 33 is fixed to a column by a means (not shown). At this time, the top end of the lower dust collection chamber 33 is separated from the bottom surface of the workpiece 101 by a distance S2 (for example, 0.3 mm). The upper dust collection chamber 32 moves in the vertical Z direction relative to the lower dust collection chamber 33.

Now, the distances (gaps) S3, S4, and S5 shown in FIG. 22(b) will be explained. The distance S3 is determined by the width of the removed portion 107, and is normally 10 to 15 mm. The distance S4 is determined by the board thickness of the workpiece 101, and is the board thickness of the workpiece 101 plus 0.2 to 0.5 mm. The distance S5 is 0.1 mm or less so that the dust collection effect does not decrease. The lower dust collection chamber 33 is connected to the dust collection duct 37. The spot height of the machining beam B1 is set to match the surface of the machining portion by a Z-axis mechanism (not shown).

4.4 Embodiment of Fourth Dust Collector

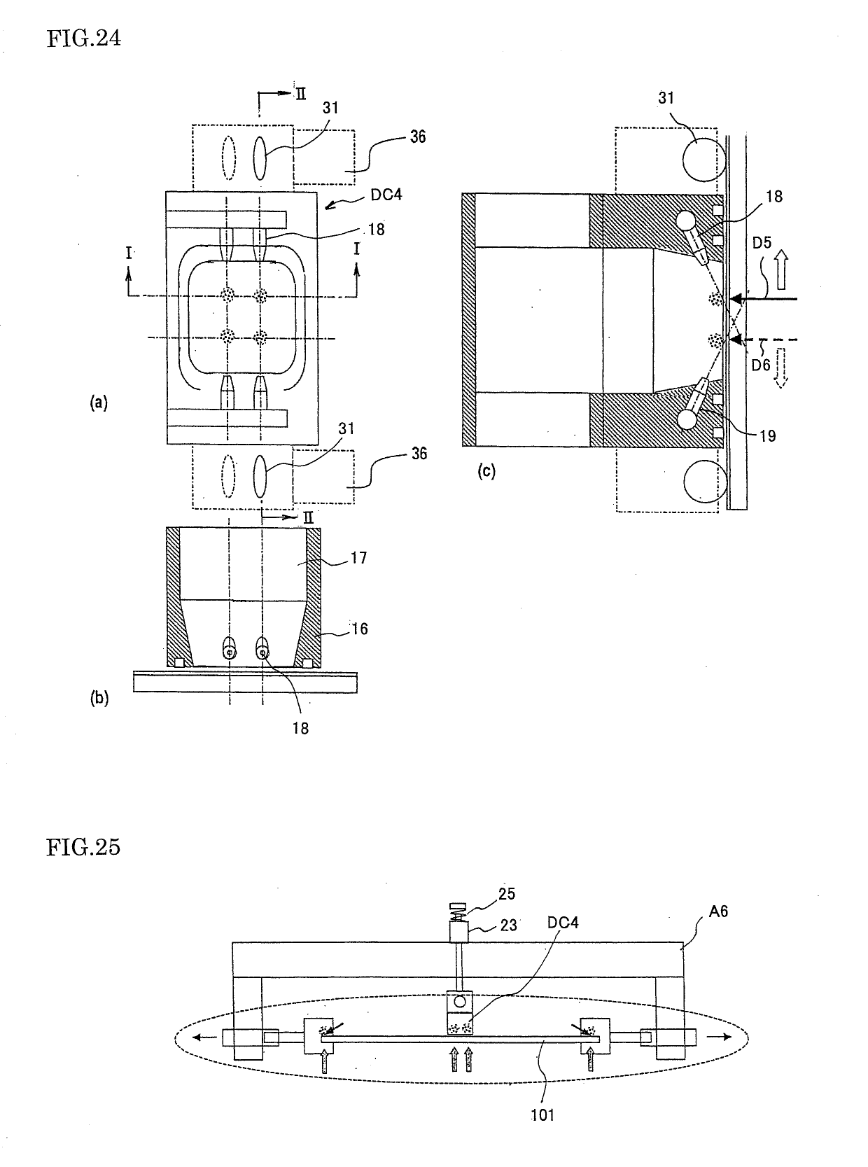

FIG. 24 is an explanatory view of a fourth dust collector (hereinafter referred to as the “dust collector DC4”) used in machining of a center portion. FIG. 24(a) is a plan view, FIG. 24(b) is a cross-sectional view along line I-I of FIG. 24(a), and FIG. 24(c) is a cross-sectional view along line II-II of FIG. 24(a).

For example, in the case of a workpiece size of 2600×2200 mm, the workpiece is divided up into four parts to be used. Therefore, not only is the periphery removed, but a removed portion having a cross shape (hereinafter referred to as a “cross-shaped removed portion”) is also formed in the center. The removal width of the cross-shaped removed portion needs to be twice the width of the removed portion 107. In the dust collector DC4 illustrated in FIG. 24, the spacing between the two nozzles 18 is ½ of the machining width. A groove is formed along the X direction using two beams simultaneously. In this way, the machining efficiency can be enhanced. The delivering direction of the nozzles 18 can also be in the Y direction. Further, if guide rollers are provided to the front and back of the dust collector DC4, deformation of the workpiece can be more effectively corrected.

FIG. 25 is a side view showing the main parts of a column A6 equipped with the dust collector DC4. The dust collector DC4 shown in FIG. 25 is mounted on a peripheral thin-film layer removal apparatus for a large workpiece.

In the case of using the dust collectors DC1 to DC4, after completion of the machining, in the discharge step, it is preferable to dry the workpiece with a dryer.

The method for delivering a cooling medium onto the worked portion is also effective in the case of machining by irradiation with the laser from the thin-film layer side.

In the dust collectors DC1 to DC4, a cooling medium such as air, mist, or liquid is delivered from the nozzles 18 and 19. In regards to this, the reason for delivering, for example, mist or water onto the worked portion will be shown below.

That is, the insulation resistance required by the removed portion 107 (portion formed by removing the thin-film layer around the periphery of the workpiece) is 2000 MΩ or greater in the case that DC 500 V is applied. In normal machining of the workpiece 101, the laser wavelength is 1064 nm, the average output is 300 W or greater, and the pulse frequency is 5 to 10 kHz. In this case, the spot diameter is 400 to 600 μm, and the necessary energy density is 16 J/cm² or greater. The thin-film layer component is scattered by the laser beam irradiation. However, at this time, the removed portion 107 momentarily enters a vacuum state. Therefore, the worked component instantaneously returns and adheres to the surface which is in a melted state. Further, spatters and debris are produced in large amounts, ionized to plasma of high temperature, and scatter on the periphery of the removed portion 107, and adhere onto the glass surface and solidify. Therefore, the insulating resistance becomes approximately 30 MΩ or less. However, if mist or water is sprayed onto the worked portion, the glass surface is covered by water. The temperature of the high temperature spatters and debris also decreases when the spatters and debris reach the glass surface. As a result, the spatters and debris are prevented from adhering onto the glass surface. In other words, the problem of worked components adhering onto the removed portion 107 is overcome. Thereby, the requirement of an insulating resistance of 2000 MΩ or greater can be achieved. Further, even in machining which uses overlapping spots in subsequent pulses, the occurrence of cracks in the glass surface due to rising temperatures at portions on the glass where the beams overlap each other can be eliminated.

### 5. Optical System

5.1 Dust Prevention Mechanism

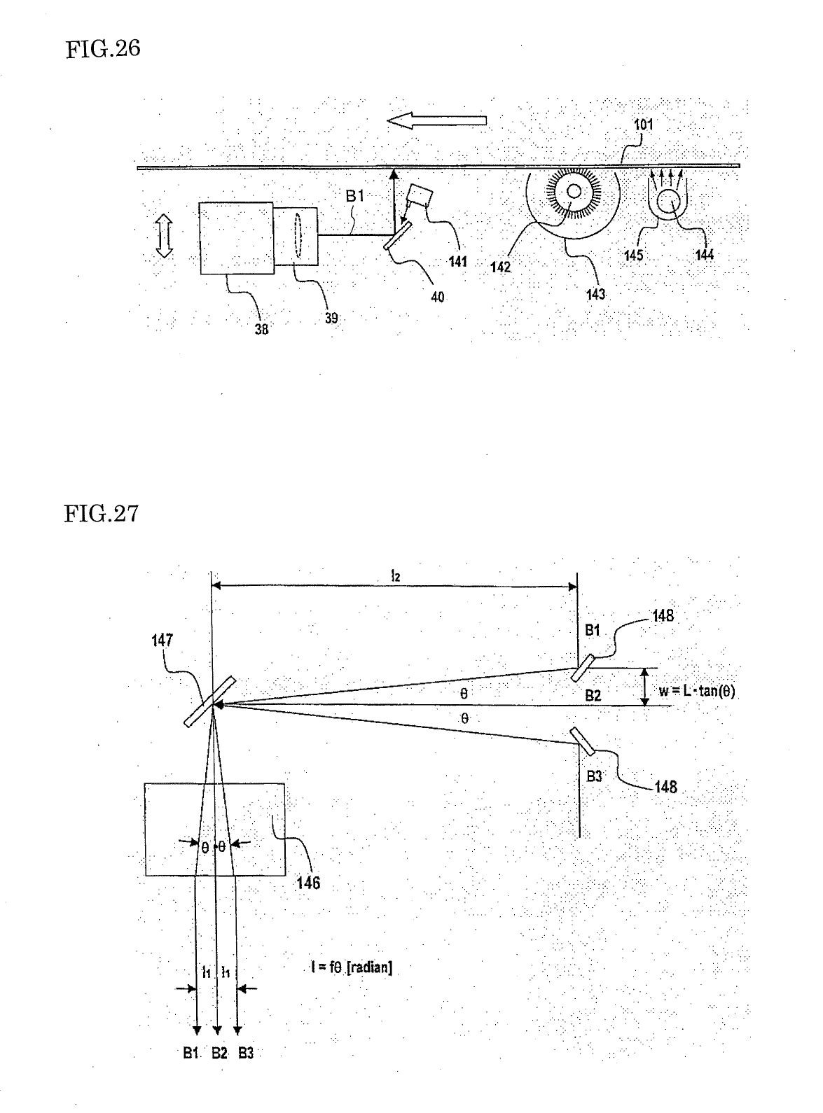

FIG. 26 is a schematic view showing a dust prevention mechanism of an optical system in the embodiment of the present invention. The arrow direction is the direction of movement of the workpiece.

In the optical system in the embodiment shown in FIG. 26, dust is removed from the workpiece 101 by a UV lamp 144 for static elimination. The removed dust drops into a dust collection duct 145 which also serves as a reflecting plate of the UV lamp 144. Afterwards, the dust is collected by a dust collector (not shown). A rotating static brush 142 is provided on the downstream side from the UV lamp 144 in the movement direction of the workpiece. The rotating anti-static brush 142 cleans the underside of the workpiece 101. A dust collection duct 143 is disposed on the outer periphery of the anti-static brush 142. Dust removed from the workpiece 101 by the anti-static brush 142 is collected by the dust collection duct 143. Subsequently, the dust is collected by a dust collector (not shown).

The position of the laser beam B1 in the XY directions is determined by a beam positioning mechanism 38. The laser beam B1 impinges on the workpiece 101 after passing through a condenser lens (fθ lens) 39 and being reflected by a mirror 40. The beam positioning mechanism 38 is supported so that it can be freely positioned in the Z direction relative to the machining head A4. An air blower 141 delivers air toward the reflective surface of the mirror 40. Therefore, even if glass dust falls from the workpiece 101, the glass dust will not remain on the reflective surface of the mirror 40.

In actual machining, high productivity, good machining quality, and high reliability of the machining are required. In order to accommodate these requirements, the laser properties are important. If a frequency near the pulse frequency at which maximum output can be obtained is used, output fluctuations of the laser will be reduced to a minimum. The beam mode (energy distribution) will also become stable in a good condition. On the other hand, in the case of using a laser oscillator for line groove machining, as is being used in the present invention, the actual capable value of the pulse frequency at which maximum output can be obtained is 80 to 120 kHz. However, the limit of the table speed is 1 m/sec. In actual machining, the hole diameter which is used is 60 μm and the beam overlap ratio is 30 to 50%. Therefore, the pulse frequency is constrained to 25 to 40 kHz. Thus, the output utilization efficiency is 50% at maximum.

5.2 Optical System

In the present embodiment, in order to enhance the output utilization efficiency, an optical system as described below is utilized. FIG. 27 is a view showing a configuration of the main parts of the optical system in the present embodiment.

In FIG. 27, a first corner mirror 147 is disposed at the entrance pupil position of an fθ lens 146 having a focal distance f. The angle of the corner mirror 147 is positioned to be 45° relative to the optical axis of the fθ lens 146. A laser beam B2 is incident so that it is coaxial with the optical axis of the fθ lens 146. Two second corner mirrors are disposed at a position separated from the first corner mirror 147 by a distance 12. These second corner mirrors are arranged such that the angles of the laser beams B1 and B3 are θ relative to the laser beam B2. The laser beams B1, B2, and B3 have the same polarization. The pulse irradiation sequence of the laser beams is shifted by 1/F. The spacing l1 is the line spacing (distance between the beam spots) at the removed portion 107, and is l1=fθ. The beam spacing w at the position of the corner mirror 148 is calculated as w=l2·tan θ.

For example, in the case of condensing the beam diameter of 10 mm using an fθ lens having a focal distance f of 10 mm, the angle θ necessary for obtaining a spot spacing l1 of the machined portion (removed portion)=10 μm is approximately 5.7°. If the necessary effective diameter of the mirrors at the position of the second corner mirrors 148 is 20 mm, the mirror spacing l2 for avoiding interference between the beam B2 and the mirrors 148 is l2=200 mm. Therefore, by leading the three beams split from a beam of 80 to 120 kHz to the single fθ lens, machining at a table speed of 1 m/sec can be achieved. Thus, the output effective utilization ratio can be increased to 100%.

The output of a high output laser used in machining to remove the periphery of a workpiece is 500 W, and the pulse frequency thereof is 5 to 6 kHz. The spot size which has been formed into a rectangular beam is 600×600 and the overlap ratio is 30 to 50%. Therefore, the machining speed is 1.5 to 2.4 m/s. Thus, the output utilization efficiency is 66% at maximum, rate-determined by the table speed. In order to enhance the output utilization efficiency, a beam having a width of 2 W and a machining pitch of W/2, formed by aligning four rectangular beams of 300×300 μm next to each other, can be used. If machining is performed using this beam, the table speed can be decreased by ½ (50%). Thus, the output utilization efficiency can be increased two fold compared to the related art.

FIG. 28 is a view showing the configuration of the optical system in the present embodiment. This configuration is an example of an optical system for machining to remove the periphery of the workpiece by a high output laser.

In FIG. 28, a laser oscillator 49 emits an emission beam (having an output of, for example, 500 W) 50 having random polarization. The emission beam 50 is split into two beams having the same energy by a beam splitter 51. The two split beams are each split into a P wave and an S wave by a first polarizing beam splitter 52. The ratio (energy) of the P waves formed by splitting by the polarizing beam splitter 52 is adjusted by a ½λ, plate 53. The ½λ plate 53 adjusts the ratio of P waves to S waves by a rotation angle. The P waves pass through a second polarizing beam splitter 54 and enter a micro-lens array (or rectangular fiber) beam shaper 56. The ratio (energy) of the S waves formed by splitting by the polarizing beam splitter 52 is adjusted by the ½λ plate 53. The ½λ, plate 53 adjusts the ratio of P waves to S waves by a rotation angle. The S waves pass through the second polarizing beam splitter 54 and enter the micro-lens array (or rectangular fiber) beam shaper 56. The cross-section of the beams which have entered the beam shaper 56 is shaped into a rectangular shape, and then the beams are supplied to the removed portion 107 (worked portion) via an fθ lens 57. The beams reflected by the second polarizing beam splitter 54 are absorbed by beam dampers 55.

Reference numbers 58, 59, and 60 in FIG. 28(a) represent the arrangement of rectangular spots in the case that both ends are machined by one spot whereas the center is machined by two spots. Reference numbers 61 and 62 in FIG. 28(b) show the arrangement of rectangular spots in the case that both sides are each machined by two rectangular spots. In order to form the beam cross-section into a rectangle, a plurality of prisms or a plurality of fiber emission outlets having a rectangular cross-section, or a fiber connector can be arranged next to each other.

A case using four beams has been explained above. However, for example, if eight beams are used and the rectangular beams are 210×210 μm, the table speed can be lowered to 35%. Further, in the above-described case, the outputs of B1 to B4 have been adjusted individually. However, if the first polarizing beam splitter 52, the ½λ plate 53, and the second polarizing beam splitter 54 are disposed at the position of the beam splitter 51 to adjust the output, the output error between the beams increases, but the number of polarizing beam splitters and ½λ plates can be decreased.

As explained above, according to the present embodiment, the following effects can be achieved:

(1) a mechanism for floating and sucking the workpiece and a workpiece clamp mechanism of a style which follows the vertical position of the workpiece are utilized. Thereby, height variations of the workpiece surface can be improved to ⅓ of that of the related art (from ±1.5 mm to ±0.05 mm). Therefore, the yield can be enhanced.

(2) The thin-film layer is worked from the underside while a cooling medium is delivered on the top surface side. Therefore, in machining of a first insulating layer and machining to remove the periphery of the workpiece, an insulating resistance of 2000 MΩ or greater can be achieved. As a result, the generating efficiency of a solar battery and the yield can be enhanced.

(3) Further, even if the pulse period is shortened (0.02 ms, pulse frequency 50 kHz), the insulating resistance can be secured and detachment at the entrance of a hole can be eliminated. Thus, it is possible to increase the speed.

(4) Reduced output machining of a maximum of 30% compared to the related art is possible. Thus, energy conservation can be achieved.

The above effects are achieved in this manner.

The present invention is not limited to the above embodiment, and various modifications are possible. The subject of the present invention encompasses all technical matters included in the technical concept of the inventions recited in the claims.

### DESCRIPTION OF REFERENCE SIGNS

1 . . . first X driving mechanism
2 . . . second X driving mechanism
3 . . . connecting plate
4 . . . workpiece-underside support mechanism
5 . . . support frame
6 . . . clamp device
7 . . . workpiece front end surface clamp mechanism
8 . . . workpiece rear end surface clamp mechanism
9 . . . workpiece side surface pressing mechanism
101 . . . workpiece
102 . . . transparent glass
A1 . . . bed
A2 . . . X movement mechanism
A3 . . . Y movement mechanism
A4 machining head
A5 . . . laser oscillator
A6 . . . column
SA . . . thin-film layer machining apparatus main body

1. (canceled)

2. (canceled)

3. (canceled)

4. (canceled)

5. An apparatus for machining a thin-film layer of a workpiece, which is a transparent glass on which a thin-film layer is disposed on a top surface thereof, comprising:
a support device for supporting the workpiece in a vertical direction by an air floatation mechanism and a suction mechanism,
a clamp device for gripping the workpiece so as to follow the movement in the vertical direction of the workpiece, and
a laser irradiating device for machining the thin-film layer by a laser beam, wherein
the laser irradiating device machines the thin-film layer on the top surface side by irradiating the workpiece with a laser beam entering through the underside of the workpiece.

6. (canceled)

7. The apparatus for machining a thin-film layer of a workpiece according to claim 5, further comprising a nozzle for delivering a cooling medium, wherein
during machining, the cooling medium is delivered from the nozzle disposed by the thin-film layer side to a position at which the laser beam emitted from the laser irradiating device is incident on the thin-film layer.

8. The apparatus for machining a thin-film layer of a workpiece according to claim 7,
wherein the cooling medium is one of a sprayed liquid, a liquid, and a gas.
